(19) United States
(12) Patent Application Publication
(10) Pub. No.: US 2026/0251696 A1
(43) Pub. Date: Aug. 27, 2026

(54) SYSTEMS AND METHODS FOR DETERMINING OPERATION PARAMETERS OF QUANTUM DOT FORMING REGIONS

(71) Applicant: Conductor Quantum, Inc., San Francisco, CA (US)

(72) Inventors: Joel Kieron PENDLETON, San Francisco, CA (US); Brandon SEVERIN, San Francisco, CA (US)

(73) Assignee: Conductor Quantum, Inc., San Francisco, CA (US)

(21) Appl. No.: 19/544,747

(22) Filed: Feb. 19, 2026

Related U.S. Application Data
(60) Provisional application No. 63/761,537, filed on Feb. 21, 2025.

(51) Int. Cl. G01R 31/28; G01R 31/30

(52) U.S. Cl. CPC G01R 31/2837; G01R 31/2846; G01R 31/3004

(57) ABSTRACT

A method for determining operation parameters for one or more quantum dot forming regions of a semiconductor quantum device, the method comprising, identifying a plurality of quantum dot related regions of the semiconductor quantum device, applying voltage to each identified quantum dot related region and measuring resulting current, classifying one or more quantum dot related regions of the semiconductor quantum device as one or more quantum dot forming regions by inputting the measured current at each identified quantum dot related region into a model trained to classify quantum dot related regions of semiconductor quantum devices based on measured current, and determining one or more operation parameters for the one or more quantum dot forming regions based on the current measured at the quantum dot related regions that are classified as quantum dot forming regions.

### CROSS-REFERENCE TO RELATED APPLICATIONS

This application claims the benefit of U.S. Provisional Application No. 63/761,537, filed Feb. 21, 2025, the entire contents of which are incorporated herein by reference.

### FIELD

This application relates generally to quantum dots, and more specifically to systems and methods for categorizing quantum dot related regions and determining operation parameters of quantum dot forming regions of a semiconductor quantum device.

### BACKGROUND

Quantum dots of a semiconductor quantum device are nanoscale structures exhibiting quantum mechanical behavior. Quantum dots may be formed by confining charge carriers (e.g., electrons or holes) in regions small enough that the quantum mechanical behavior, like discrete energy levels, is observable. For instance, quantum dots may be formed by applying a voltage to electrodes lithographically fabricated on the semiconductor quantum device to electrostatically confine a discrete number of charge carriers in a region. Using one or more operation parameters, each quantum dot of the quantum dots of the semiconductor quantum device can be formed and/or operated and used in a variety of applications, such as quantum computing or photovoltaics.

However, quantum dots may be unable to be formed (e.g., charge carriers cannot be confined) due to fabrication imperfections, contaminants in the semiconductor quantum device, poor fabrication design, poor electrical connectivity, etc. As such, it may be relevant to test and categorize quantum dot related regions (e.g., regions in which quantum dots may or may not be formed) of the semiconductor quantum device to identify quantum dot forming regions (e.g., regions in which quantum dots may be formed). Conventionally, quantum dot forming regions are identified by visually examining, in manual or semi-automated methods, data to determine whether the data represents a quantum dot forming region. For instance, the data may represent a quantum dot forming region if the data includes a transition from a low current to a high current, which indicates the data is associated with a quantum dot forming region in the pinch-off regime (e.g., a quantum dot may be formed). The pinch-off regime may occur when the charge carriers are depleted such that channel conductance between lithographically fabricated source and drain electrodes diminishes significantly. However, the manual or semi-automated methods are often time-consuming, inaccurate, and unscalable, thus limiting the applicability of quantum dots in quantum computing applications as quantum computing may require identifying a great number (e.g., hundreds or thousands) of quantum dot forming regions.

Additionally, the one or more operation parameters for each quantum dot related region are often unreliable or inaccurate. Existing computational methods attempt to determine operation parameters of all quantum dot related regions, regardless of whether the data associated with each quantum dot related region represents a quantum dot forming region. Furthermore, the existing computational methods often struggle to determine operation parameters from noisy or incomplete data, thus minimizing the number of quantum dot forming regions whose operation parameters can be determined. Accordingly, improved systems and methods are needed to robustly and automatically identify quantum dot forming regions of the semiconductor quantum devices and determine operation parameters of quantum dot forming regions.

### SUMMARY

Described herein are systems and methods for identifying quantum dot forming regions of a semiconductor quantum device based on whether data associated with quantum dot related regions represents quantum dot forming regions. The quantum dot forming regions of the semiconductor quantum device may be identified by: 1) identifying a plurality of quantum dot related regions, 2) testing each quantum dot related region by applying voltage to the quantum dot related region and measuring current generated in response to applying the voltage, 3) inputting data obtained from testing the quantum dot related regions into a model trained to identify the quantum dot forming regions, and 4) obtaining outputs from the model indicating whether the data inputted into the trained model represents a quantum dot forming region.

Identifying the plurality of quantum dot related regions may include receiving a position for each quantum dot related region at which each quantum dot related region can be tested. The positions may be received by a control system configured to test each quantum dot related region at the received position. For instance, the positions may be received as inputs from a user or outputs from an algorithm performed by the control system. The positions at which each quantum dot related region can be tested may be associated with one or more electrodes fabricated on the semiconductor quantum device used to define each quantum dot related region.

Testing the quantum dot related regions may include applying a voltage, or a plurality of voltages, to each position at which each quantum dot related region can be tested (e.g., the position received by a control system). In response to the voltage, or the plurality of voltages, a current, or a plurality of currents, is measured at the position at which each quantum dot related region can be tested. In some examples, testing the quantum dot related regions includes charge sensing measurements, reflectometry measurements, or a combination of charge sensing and reflectometry measurements, such as described herein. The data from testing the position at which each quantum dot related region can be tested may be the measured current, or the plurality of measured currents, and/or the applied voltage, or the plurality of applied voltages.

The data obtained from testing the position at which each quantum dot related region can be tested may be inputted into a trained model configured to determine whether the data indicates a quantum dot forming region. The trained model may be configured to handle a variety of data including data with excessive noise, a reduced signal-to-noise-ratio, incomplete information, etc. because the trained model is trained using a broad data distribution (e.g., broad range of current and voltage values), a broad quantum dot parameter distribution, and/or data with various noise profiles. The trained model may attempt to identify one or more features indicative of a quantum dot forming region, such as a transition from a low current to a high current (e.g., pinch-off regime). The trained model may produce one or more outputs indicating whether the data represents a quantum dot forming region. For instance, the trained model may produce a binary label, a probability, or a confidence score.

Described herein are also systems and methods for determining one or more operation parameters for the quantum dot forming regions. The one or more operation parameters may be used to form the quantum dots in the regions or used as initial conditions for subsequent quantum dot systems and methods that form or calibrate the quantum dots. The one or more operation parameters may be determined for each quantum dot forming region by: 1) identifying a functional form that represents the data, 2) fitting the functional form to the data using an optimization algorithm, and 3) determining the one or more operation parameters from the fitted functional form.

The data for each quantum dot forming region may be the data obtained from testing each quantum dot forming region's respective quantum dot related region prior to being identified as a quantum dot forming region. Alternatively, the data for each quantum dot forming region may be data obtained from testing each quantum dot forming region by applying voltage and measuring current at a position at which each quantum dot forming region can be tested. The data may be normalized to reduce scale dependences and may be filtered to reduce noise and outliers. The functional form may be any equation that represents the data, for instance a hyperbolic tangent functional form. The optimization algorithm may fit the functional form to the data by adjusting parameters that parameterize the functional form to minimize the error between the data and the functional form. With the fitted functional form, one or more operation parameters may be determined for each quantum dot forming region by identifying a current(s) and/or a voltage value(s) associated with a feature inherent to each operation parameter of the one or more operation parameters. Examples of the one or more operation parameters include cutoff voltage, transition voltage, and saturation voltage.

The one or more quantum dot forming regions of the semiconductor quantum device may form a quantum device. The quantum device may also include a control system configured to operate each quantum dot forming region using the one or more operation parameters. In some examples, the control system is configured to use the one or more operation parameters in additional quantum dot systems and methods to form quantum dots in the quantum dot forming regions and/or calibrate the quantum dots in the quantum dot forming regions. For instance, the control system may use the one or more operation parameters to measure Coulomb blockade oscillations (e.g., peaks in a plot of measured current versus applied voltage) or charge stability diagrams. As such, the quantum device may be used in quantum applications and/or the additional quantum dot systems and methods.

According to some examples, a method for determining operation parameters for one or more quantum dot forming regions of a semiconductor quantum device, the method including identifying a plurality of quantum dot related regions of the semiconductor quantum device, applying voltage to each identified quantum dot related region and measuring resulting current, classifying one or more quantum dot related regions of the semiconductor quantum device as one or more quantum dot forming regions by inputting the measured current at each identified quantum dot related region into a model trained to classify quantum dot related regions of semiconductor quantum devices based on measured current, and determining one or more operation parameters for the one or more quantum dot forming regions based on the current measured at the quantum dot related regions that are classified as quantum dot forming regions.

In any of these examples, a composition of the semiconductor quantum device comprises Group-IV semiconductors, Group-IV compound semiconductors, doped semiconductors, or Group-III and Group-V compound semiconductors. In any of these examples, each quantum dot related region of the plurality of quantum dot related regions of the semiconductor quantum device has one to ten electrodes. In any of these examples, the one or more operation parameters comprise cutoff voltage, transition voltage, or saturation voltage.

In any of these examples, applying voltage to each identified quantum dot related region and measuring the resulting current includes applying a constant voltage and measuring a plurality of resulting currents. In any of these examples, the constant voltage is applied to one or more electrodes of each quantum dot related region of the plurality of quantum dot related regions. In any of these examples, applying voltage to each identified quantum dot related region and measuring the resulting current includes applying a plurality of voltages and measuring a resulting current for each voltage in the plurality of voltages. In any of these examples, the plurality of voltages is applied to the one or more electrodes of each quantum dot related region in the plurality of quantum dot related regions.

In any of these examples, inputting the measured current into the model trained to classify quantum dot related regions includes inputting a plurality of measured currents. In any of these examples, inputting the measured current into the model trained to classify quantum dot related regions further includes inputting the constant voltage. In any of these examples, inputting the measured current into the model trained to classify quantum dot related regions further includes inputting the plurality of voltages.

In any of these examples, the model is a support vector machine model, a K-nearest neighbor model, a decision tree model, an artificial neural network model, a logistic regression model, a naïve Bayes model, a linear discriminant analysis model, or a quadratic discriminant analysis model. In any of these examples, the artificial neural network model is a convolutional neural network model, a recurrent neural network model, or an attention-based neural network. In any of these examples, training the model trained to classify quantum dot related regions includes training an un-trained model with labeled simulated current. In any of these examples, training the model trained to classify quantum dot related regions further includes training the un-trained model with a plurality of labeled simulated currents.

In any of these examples, obtaining the labeled simulated current includes generating one or more data generation models representing quantum behavior of one or more quantum dots and inputting labeled simulated voltage to the one or more data generation models and receiving labeled simulated current. In any of these examples, inputting labeled simulated voltage into the one or more data generation models and receiving labeled simulated current includes inputting a labeled simulated voltage and receiving a plurality of labeled simulated currents. In any of these examples, the labeled simulated voltage inputted into the one or more data generation models is further used for training the model trained to classify quantum dot related regions. In any of these examples, inputting labeled simulated voltage into the one or more data generation models and receiving labeled simulated current further includes inputting a plurality of labeled simulated voltages and receiving a labeled simulated current for each labeled simulated voltage in the plurality of labeled simulated voltages. In any of these examples, the plurality of labeled simulated voltages inputted into the one or more data generation models is further used for training the model trained to classify quantum dot related regions.

In any of these examples, training the model trained to classify quantum dot related regions further includes training an un-trained model with labeled measured current. In any of these examples, the labeled measured current includes a plurality of labeled measured current. In any of these examples, obtaining the labeled measured current includes obtaining measured current from one or more quantum dot related regions of one or more semiconductor quantum devices, wherein measured current is obtained by applying voltage to the one or more quantum dot related regions of the one or more semiconductor quantum devices and measuring resulting current, and labeling the measured current based on whether the measured current indicates the one or more quantum dot related regions are quantum dot forming regions. In any of these examples, the voltage applied to the one or more quantum dot related regions is further used for training the model trained to classify quantum dot related regions. In any of these examples, the measured current includes a plurality of measured currents. In any of these examples, the voltage includes a plurality of voltages.

In any of these examples, classifying each of the quantum dot related regions of the semiconductor quantum device using the model trained to classify quantum dot related regions includes receiving from the model one or more outputs for each of the plurality of quantum dot related regions. In any of these examples, the one or more outputs from the model is a binary label, wherein a first state of the binary label indicates that the quantum dot related region is a quantum dot forming region and a second state of the binary label indicates that the quantum dot related region is quantum dot non-forming region. In any of these examples, the one or more outputs from the model is a probability, wherein the probability indicates a likelihood that the quantum dot related region is a quantum dot forming region. In any of these examples, the one or more outputs from the model is a confidence score, wherein the confidence score indicates a likelihood that the quantum dot related region is a quantum dot forming region.

In any of these examples, determining one or more operation parameters for each quantum dot forming region of one or more quantum dot forming regions based on the measured current at the quantum dot related regions includes fitting a functional form to the measured current using an optimization algorithm and determining one or more operation parameters using the fitted functional form. In any of these examples, normalizing the measured current and applying a filter to the normalized measured current. In any of these examples, applying a filter to the measured current and normalizing the filtered measured current. In any of these examples, determining one or more operation parameters based on the measured current further includes determining one or more operation parameters based on a plurality of the measured current. In any of these examples, determining one or more operation parameters based on the measured current further includes determining one or more operation parameters based on the plurality of the measured current and an applied voltage. In any of these examples, determining one or more operation parameters based on the measured current further includes determining one or more operation parameters based on plurality of the measured current and a plurality of the applied voltage.

In any of these examples, the functional form is a hyperbolic tangent function parameterized with three parameters. In any of these examples, the three parameters parameterize amplitude, steepness, and horizontal offset. In any of these examples, the optimization algorithm is a nonlinear least squares algorithm, a Nelder-Mead algorithm, or a gradient descent algorithm. In any of these examples, the optimization algorithm receives one or more starting conditions and one or more parameter bounds. In any of these examples, the optimization algorithm fits the filtered and normalized measured current by adjusting parameters parameterizing the functional form. In any of these examples, adjusting the parameters parameterizing the functional form includes minimizing the error between the filtered and normalized measured current and the functional form.

In any of these examples, determining the one or more operation parameters from the fit includes identifying onset of conduction, change between non-conductive and conductive states, or stable conduction. In any of these examples, the onset of the conduction is the cutoff voltage, the change between non-conductive and conductive states is the transition voltage, and the stable conduction is the saturation voltage. In any of these examples, the semiconductor quantum device operates at temperatures in a range of 1 mK to 10,000 mK. In any of these examples, the one or more operation parameters are used to operate the one or more quantum dot forming regions of the semiconductor quantum device.

According to some examples, a quantum device including one or more quantum dot forming regions, wherein each quantum dot forming region is configured to operate using one or more operation parameters, including a semiconductor quantum device and a control system, including one or more processors, configured to operate the quantum device including the one or more quantum dot forming regions using the one or more operation parameters of each quantum dot forming region, wherein the one or more operation parameters of each quantum dot forming region have been determined by identifying a plurality of quantum dot related regions of the semiconductor quantum device, applying voltage to each identified quantum dot related region and measuring resulting current, classifying one or more quantum dot related regions of the semiconductor quantum device as one or more quantum dot forming regions by inputting the measured current at each identified quantum dot related region into a model trained to classify quantum dot related regions of semiconductor quantum devices based on measured current, and determining one or more operation parameters for the one or more quantum dot forming regions based on the current measured at the quantum dot related regions that are classified as quantum dot forming regions.

### BRIEF DESCRIPTION OF THE DRAWINGS

FIG. 1 illustrates an exemplary system for identifying one or more quantum dot forming regions of a semiconductor quantum device, according to some embodiments.

FIG. 2 is a plot of a plurality of current measured at a position at which a quantum dot related region can be tested versus a plurality of voltage applied at the position at which the quantum dot related region can be tested, according to some embodiments.

FIG. 3 illustrates an exemplary method for determining one or more operation parameters of one or more quantum dot forming regions, according to some embodiments.

FIG. 4 illustrates an exemplary method for generating labeled simulated current (or plurality of current) and/or labeled simulated voltage (or plurality of voltages) and training an un-trained model, according to some embodiments.

FIG. 5 illustrates an exemplary method for training an un-trained model with labeled simulated data and/or labeled empirical data, according to some embodiments.

FIG. 6 illustrates an exemplary method for identifying one or more quantum dot forming regions of a semiconductor quantum device and determining one or more operation parameters for the one or more quantum dot forming regions, according to some embodiments.

FIG. 7 illustrates an exemplary quantum device configured to operate one or more quantum dot forming regions using one or more operation parameters, according to some embodiments.

FIG. 8 illustrates an exemplary computing unit, according to some embodiments.

### DETAILED DESCRIPTION

Described herein are systems and methods for identifying quantum dot forming regions of a semiconductor quantum device. The quantum dot forming regions of the semiconductor quantum device may be identified by: 1) identifying a plurality of quantum dot related regions, 2) testing the quantum dot related regions by applying voltage to the quantum dot related regions and measuring current generated in response to applying the voltage, 3) inputting data from testing the quantum dot related regions into a model trained to determine whether the quantum dot related regions are quantum dot forming regions, and 4) obtaining outputs from the model indicating whether the quantum dot related regions are quantum dot forming regions.

Identifying the plurality of quantum dot related regions may include receiving a position for each quantum dot related region at which each quantum dot related region can be tested. The positions at which each quantum dot related region can be tested may be received by a control system configured to test each quantum dot related region at the received position. For instance, the positions may be received as inputs from a user or outputs from an algorithm performed by the control system. The positions at which each quantum dot related region can be tested may be associated with one or more electrodes fabricated on the semiconductor quantum device used to define each quantum dot related region.

Testing the quantum dot related regions may include applying a voltage, or a plurality of voltages, to each position at which each quantum dot related region can be tested (e.g., each position received by a control system). In response to the voltage, or the plurality of voltages, a current, or a plurality of currents, may be measured at each position at which each quantum dot related region can be tested. In some examples, testing the quantum dot related regions includes charge sensing measurements, reflectometry measurements, or a combination of charge sensing and reflectometry measurements, such as described herein. In some examples, a constant voltage is applied to each position and a plurality of currents are measured. In some examples, a plurality of voltages is applied to each position and a current, or a plurality of currents, is measured in response to each voltage in the plurality of voltages. The data from testing each position may be the measured current, or the plurality of measured currents, and/or the applied voltage, or the plurality of applied voltages.

The data from testing each position may be inputted into a trained model configured to determine whether the data indicates a quantum dot forming region (e.g., a quantum dot may be formed in the region). The trained model may be configured to handle a variety of data including data with excessive noise, a reduced signal-to-noise-ratio, incomplete information, etc. because the trained model is trained using a broad data distribution (e.g., broad range of current and voltage values), a broad quantum dot parameter distribution, and/or data with various noise profiles. For instance, the model may be trained using labeled simulated data generated by one or more data generation models and/or labeled empirical data obtained from testing quantum dots related regions. The trained model may attempt to identify one or more features indicative of a quantum dot forming region, such as a transition from a low current to a high current (e.g., pinch-off regime). The trained model may produce one or more outputs indicating whether the data represents a quantum dot forming region. For instance, the trained model may produce a binary label, such that a first state of the binary label indicates the data represents a quantum dot forming region and a second state of the binary label indicates the data represents a quantum dot non-forming region (e.g., a quantum dot may not be formed). The trained model may produce a probability or a confidence score indicating a likelihood that the data represents a quantum dot forming region.

Described herein are also systems and methods for determining one or more operation parameters for the quantum dot forming regions. The one or more operation parameters may be used to form the quantum dots in the quantum dot forming regions or used as initial conditions for subsequent quantum dot systems and methods that form or calibrate the quantum dots in the quantum dot forming regions. The one or more operation parameters may be determined for each quantum dot forming region by: 1) identifying a functional form that represents the data, 2) fitting the functional form to the data using an optimization algorithm, and 3) determining the one or more operation parameters from the fitted functional form.

The data for each quantum dot forming region may be the data obtained from testing the previously unidentified quantum dot related region. Alternatively, the data for each quantum dot forming region may be data obtained from testing each quantum dot forming region by applying voltage and measuring current at each position at which each quantum dot forming region can be tested. The data may be normalized to reduce scale dependences and may be filtered to reduce noise and outliers. The functional form may be any equation that represents the data, for instance a hyperbolic tangent functional form. The functional form may be parameterized by at least one parameter. For instance, the hyperbolic tangent functional form includes parameters a, b, and c that parameterize the amplitude, steepness, and horizontal offset, respectively. The optimization algorithm may fit the functional form to the data by adjusting the at least one parameter parameterizing the functional form to minimize the error between the data and the functional form. With the fitted functional form, one or more operation parameters may be determined for each quantum dot forming region by identifying a current(s) and/or a voltage value(s) associated with a feature inherent to each operation parameter of the one or more operation parameters. For instance, a cutoff voltage operation parameter may be determined by identifying the voltage value at which the fitted functional form drops below a pre-defined threshold. A transition voltage operation parameter may be determined by identifying the voltage value at which the fitted functional form has a maximum slope. A saturation voltage operation parameter may be determined by identifying the voltage value at which the fitted functional form flattens to a maximum current value. The saturation voltage operation parameter may represent a stable conducting region of each quantum dot forming region.

The one or more quantum dot forming regions of the semiconductor quantum device, identified as quantum dot forming regions using systems and methods described herein, may form a quantum device. The quantum device may include a control system configured to operate each quantum dot forming region using the one or more operation parameters determined using the systems and methods described herein. In some examples, the control system is configured to use the one or more operation parameters in additional quantum dot systems and methods to form or calibrate the quantum dots in the quantum dot forming regions. For instance, the control system may use the one or more operation parameters to measure Coulomb blockade oscillations (e.g., peaks in a plot of measured current versus applied voltage) or charge stability diagrams. As such, the quantum device may be used in quantum applications and/or the additional quantum dot systems and methods.

The following description sets forth exemplary systems, parameters, and the like. It should be recognized, however, that such description is not intended as a limitation on the scope of the present disclosure but is instead provided as a description of exemplary embodiments.

Although the following description uses terms “first,” “second,” etc. to describe various elements, these elements should not be limited by the terms. These terms are only used to distinguish one element from another. For example, a first graphical representation could be termed a second graphical representation, and, similarly, a second graphical representation could be termed a first graphical representation, without departing from the scope of the various described embodiments. The first graphical representation and the second graphical representation are both graphical representations, but they are not the same graphical representation.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

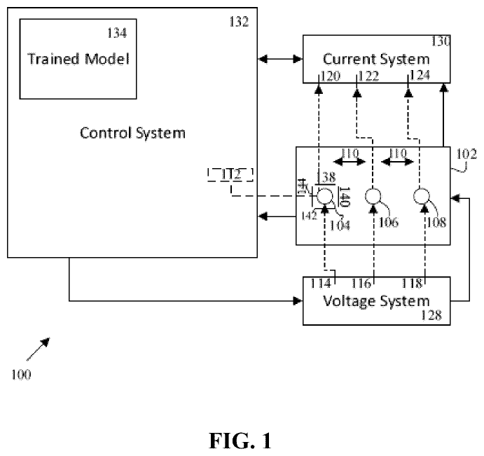

One or more quantum dots of a semiconductor quantum device may be formed by confining charge carriers in a region small enough that quantum mechanical behavior, such as discrete energy levels, is observable. Each of the one or more quantum dots may be operated or formed using one or more operation parameters, such as cutoff voltage, transition voltage, or saturation voltage. However, the one or more quantum dots may be unable to be formed (e.g., charge carriers cannot be confined) due to fabrication imperfections, contaminants in the semiconductor quantum device, poor fabrication design, poor electrical functionality, etc. As such, it may be relevant to identify one or more quantum dot forming regions (e.g., regions in which quantum dots may be formed) of the semiconductor quantum device. FIG. 1 illustrates an exemplary system 100 configured to identify one or more quantum dot forming regions of a semiconductor quantum device 102.

### Quantum Dot Related Regions of a Semiconductor Quantum Device

The semiconductor quantum device 102 may be composed of any semiconductor material or any combination of semiconductor materials. For instance, the semiconductor quantum device 102 may be composed of Group-IV semiconductors (e.g., silicon, germanium, tin, etc.), Group-IV compound semiconductors (e.g., silicon germanium, silicon tin, etc.), doped semiconductors (e.g., boron doped silicon, phosphorus doped silicon, etc.), and/or Group-III and Group-V compound semiconductors (e.g., aluminum arsenide, gallium arsenide, indium arsenide, aluminum gallium arsenide, indium gallium arsenide, etc.). The semiconductor quantum device 102 includes one or more quantum dot related regions, such as quantum dot related region 104, 106, and/or 108, that may be designed to form a quantum dot.

The semiconductor quantum device 102 may include any integer number of quantum dot related regions. In some examples, the semiconductor quantum device 102 includes at least 1 quantum dot related region, at least 10 quantum dot related regions, at least 100 quantum dot related regions, at least 1,000 quantum dot related regions, at least 10,000 quantum dot related regions, at least 100,000 quantum dot related regions, at least 1,000,000 quantum dot related regions, at least 10,000,000 quantum dot related regions, at least 100,000,000 quantum dot related regions, or at least 1,000,000,000 quantum dot related regions. In some examples, the semiconductor quantum device 102 includes 1 quantum dot related regions, 10 quantum dot related regions or less, 100 quantum dot related regions or less, 1,000 quantum dot related regions or less, 10,000 quantum dot related regions or less, 100,000 quantum dot related regions or less, 1,000,000 quantum dot related regions or less, 10,000,000 quantum dot related regions or less, 100,000,000 quantum dot related regions or less, or 1,000,000,000 quantum dot related regions or less. A quantum dot may be formed in each quantum dot related region of the semiconductor quantum device 102. As such, the semiconductor quantum device 102 may include at least 1 quantum dot, at least 10 quantum dots, at least 100 quantum dots, at least 1,000 quantum dots, at least 10,000 quantum dots, at least 100,000 quantum dots, at least 1,000,000 quantum dots, at least 10,000,000 quantum dots, at least 100,000,000 quantum dots, or at least 1,000,000,000 quantum dots. In some examples, the semiconductor quantum device 102 includes 1 quantum dot, 10 quantum dots or less, 100 quantum dots or less, 1,000 quantum dots or less, 10,000 quantum dots or less, 100,000 quantum dots or less, 1,000,000 quantum dots or less, 10,000,000 quantum dots or less, 100,000,000 quantum dots or less, or 1,000,000,000 quantum dots or less.

The one or more quantum dot related regions of the semiconductor quantum device 102 may be designed to be regions in which quantum dots can be formed using any method(s) that confines one or more charge carriers (e.g., one or more electrons or one or more holes) in a region small enough that quantum mechanical behavior is observable. For instance, the one or more quantum dot related regions, such as quantum dot related region 104, may be designed to be regions in which quantum dots can be formed by fabricating one or more electrodes, such as electrodes 138, 140, 142, and 144, on the semiconductor quantum device 102. The one or more electrodes may be used to form a quantum dot in each region of the semiconductor quantum device. For instance, applying voltage, or current, to the electrodes 138, 140, 142, and 144 may electrostatically confine one or more charge carriers in the region 104. The voltage, or the current, may be applied by a battery, generator, power supply, arbitrary waveform generator, digital-to-analog converter (DAC), etc. As such, the electrodes 138, 140, 142, and/or 144 may define the quantum dot related region 104. Each quantum dot related region in the one or more quantum dot related regions may be defined using 1 to 10 electrodes, for instance, 1 electrode, 2 electrodes, 3 electrodes, 4 electrodes, 5 electrodes, 6 electrodes, 7 electrodes, 8 electrodes, 9 electrodes, or 10 electrodes. In some examples, the one or more electrodes include one or more gate electrodes, one or more source electrodes (e.g., one or more source contacts or one or more source terminals), and/or one or more drain electrodes (e.g., one or more drain contacts or one or more drain terminals).

The one or more electrodes for each quantum dot related region in the one or more quantum dot related regions may be fabricated according to a fabrication design. The fabrication design may define, for each electrode in the one or more electrodes for each quantum dot related region, a position (e.g., position on the semiconductor quantum device 102), a geometry (e.g., length, width, height, shape, etc.), electrical connections (e.g., one or more current/voltage traces connecting to the electrode), etc. The one or more electrodes defining each quantum dot related region may be irregularly, or regularly, patterned on the semiconductor quantum device 102. For instance, the one or more electrodes defining each quantum dot related region may be regularly patterned, such that each quantum dot related region is separated by a distance 110.

In some examples, a minimum distance in all directions (e.g., up, down, left, right, diagonal, etc.) between adjacent quantum dot related regions is in a range of about 1 nm to 1000 nm, for instance 1 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1000 nm. In some examples, the minimum distance between adjacent quantum dot related regions is greater than or equal to 1 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1000 nm. In some examples, the minimum distance between adjacent quantum dot related regions is less than or equal to 1 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1000 nm.

### Receive a Position of Each Quantum Dot Related Region

The system 100 may include a control system 132 configured to receive positions at which each quantum dot related region can be tested (e.g., identifying quantum dot related regions of the semiconductor quantum device 102). Each quantum dot related region may refer to each quantum dot related region of the one or more quantum dot related regions of the semiconductor quantum device 102. For instance, each quantum dot related region may refer to each quantum dot related region of the quantum dot related regions 104, 106, and 108 of the semiconductor quantum device 102. In some examples, each quantum dot related region refers to each quantum dot related region of a subset of the one or more quantum dot related regions of the semiconductor quantum device 102. For instance, each quantum dot related region may refer to each quantum dot related region of the quantum dot related regions 104 and/or 106 (e.g., a subset of the quantum dot related regions 104, 106, and 108).

The control system 132 may receive a position for each quantum dot related region, such that the position for each quantum dot related region is the position at which the quantum dot related region can be tested. The position for each quantum dot related region may hereafter be referred to as each position at which each quantum dot related region can be tested or as merely each position. The control system 132 may receive each position as an input or assignment provided by a user. In some examples, the user inputs each position as a position in a coordinate system, such as a cartesian coordinate system, a polar coordinate system, a cylindrical coordinate system, or a spherical coordinate system. For instance, the user may input a (x, y, z) position at which the quantum dot related region 104 can be tested, a (x, y, z) position at which the quantum dot 106 can be tested, and/or a (x, y, z) position at which the quantum dot 108 can be tested. Each quantum dot related region may then be tested by applying a voltage, or a plurality of voltages, to each (x, y, z) position and measuring a resulting current, or a plurality of resulting currents, from the same, or a different, (x, y, z) position associated with each quantum dot related region. In some examples, the user assigns each position of each quantum dot related region to a marker or channel inherent to the control system 132. For instance, the user may assign a channel 112 of the control system 132 to the quantum dot related region 104, such that any commands, instructions, triggers, etc. from the control system 132 associated with the channel 112 may be directed to or otherwise associated with the quantum dot related region 104. In some examples, the user inputs at least one parameter associated with each quantum dot related region, such that the control system 132 uses the at least one parameter to test each quantum dot related region (e.g., the at least one parameter associated with each quantum dot related region acts as a position of each quantum dot related region). For instance, the electrodes 138, 140, 142, and/or 144 defining the quantum dot related region 104 may be designed such that a quantum dot may be formed in the quantum dot related region 104 if a specific voltage range, or specific voltage, is applied to the electrodes. The quantum dot related region 106 may also be defined by one or more electrodes designed such that a quantum dot may be formed in the quantum dot related region 106 if a different specific voltage range, or voltage, is applied to the one or more electrodes defining the quantum dot related region 106. As such, the user may input the specific voltages, or voltage ranges, uniquely associated with each quantum dot related region, such that when the control system 132 applies the specific voltage, or the voltage range, associated with each quantum dot related region to the semiconductor quantum device 102, the quantum dot related region associated with that specific voltage, or voltage range, can be tested.

In some examples, the control system 132 receives each position at which each quantum dot related region can be tested as an algorithm output. For instance, the control system 132 may be configured with an algorithm that can output each position of each quantum dot related region from an input of a fabrication design, such as the fabrication design described in reference to fabricating the electrodes 138, 140, 142, and 144. In some examples, the control system 132 is configured with an algorithm that can output each position from an input of one or more electrical connections. For instance, each quantum dot related region may be electrically connected to the control system 132 via an electrical connection, which may be one or more cables, one or more adaptors, one or more outputs from one or more other systems (e.g., voltage system 128 and/or current system 130), etc. The electrical connections for each quantum dot related region may be inputted into an algorithm that outputs an identifier for each electrical connection. As such, any commands, instructions, triggers, etc. from the control system 132 referencing each identifier may be directed to or otherwise associated with each quantum dot related region via the electrical connection. In some examples, the user inputs the identifier for each electrical connection.

In some examples, each position at which each quantum dot related region can be tested is associated with the one or more electrodes used to define each quantum dot related region. For instance, applying voltage to the one or more electrodes of each quantum dot related region may vary the charge carrier population of each quantum dot related region. The variation of the charge carrier population may be measured as a current. As such, each position at which each quantum dot related region can be tested may be the one or more electrodes of each quantum dot related region. The position of the one or more electrodes of each quantum dot related region may be received by the control system 132 using any of the aforementioned methods, such as a user input or algorithm output. In some examples, each position at which each quantum dot related region can be tested is the position of the one or more current/voltage traces connected to each electrode in the one or more electrodes used to form each quantum dot related region. The position of the one or more current/voltage traces of each quantum dot related region may be similarly received by the control system 132 using any of the aforementioned methods. In some examples, the control system 132 receives at least two positions at which each quantum dot related region can be tested. For instance, the control system 132 may receive a position for each quantum dot related region at which the voltage (or the plurality of voltages) can be applied and a position for each quantum dot related region at which the resulting current (or the plurality of resulting currents) can be measured from.

### Test Each Quantum Dot Related Region

The system 100 may include the voltage system 128 and the current system 130, which are configured to test each quantum dot related region by applying voltage to each position received by the control system 132 using the voltage system 128 and measuring current from each position received by the control system 132 using the current system 130 (e.g., applying voltage to each identified quantum dot related region and measuring current). The voltage system 128 may be any system configured to apply a voltage, or a plurality of voltages, to each position of each quantum dot related region. For instance, the voltage system 128 may be a battery, generator, power supply, arbitrary waveform generator, DAC, etc. The current system 130 may be any system configured to measure a current, or a plurality of currents, resulting from the voltage, or plurality of voltages, applied by the voltage system 128 from each position of each quantum dot related region. For instance, the current system 130 may be a multimeter, ammeter, current clamp, current probe, analog-to-digital convertor, digitizer, data acquisition card, etc. A person of skill in the art will appreciate that the current system 130 may be configured to: 1) amplify a current, or a plurality of currents, resulting from the voltage, or the plurality of voltages, applied by the voltage system 128 and/or convert the current, or the plurality of currents, to a voltage, or a plurality of voltages, respectively, and 2) measure the amplified voltage, or the plurality of amplified voltages (or measure the amplified current, or the plurality of amplified currents). For instance, the current system 130 may include a transimpedance amplifier that converts and amplifies the current, or the plurality of currents, resulting from the voltage, or the plurality of voltages, applied by the voltage system 128. The current system 130 may include a multimeter, analog-to-digital convertor, digitizer, data acquisition card, etc. configured to measure the amplified voltage, or the plurality of amplified voltages (or the amplified current, or the plurality of amplified currents). The control system 132 may convert the measured amplified voltage, or the plurality of measured amplified voltages, to a current, or a plurality of currents, respectively. For instance, the control system 132 may include software and/or an algorithm configured to take as an input the measured amplified voltage, or the plurality of measured amplified voltages, and output the current, or the plurality of currents, respectively. In some examples, the current system 130 converts the measured voltage, or the plurality of measured voltages, into a current, or a plurality of currents, respectively.

The voltage system 128 may be electrically connected to each position at which each quantum dot related region can be tested. In some examples, the voltage system 128 is electrically connected via an electrical connection (e.g., cables, adaptors, etc.) to each position at which each quantum dot related region can be tested. For instance, voltage output 114 of the voltage system 128 may be connected to the position at which the quantum dot related region 104 can be tested, such as the electrodes 138, 140, 142, and/or 144. Similarly, voltage output 116 may be connected to the position at which the quantum dot related region 106 can be tested, and voltage output 118 may be connected to the position at which the quantum dot related region 108 can be tested.

The voltage system 128 may also be connected to the control system 132. The control system 132 may command, instruct, trigger, etc. the voltage system 128 to apply the voltage, or the plurality of voltages, to each position at which each quantum dot related region can be tested (e.g., each position received by the control system 132). For instance, if the position at which quantum dot related region 104 can be tested is electrically connected to the voltage output 114 of the voltage system 128, the position received by the control system 132 for the quantum dot related region 104 may be an identifier A. As such, referencing the identifier A, the control system 132 may command, instruct, trigger, etc. the voltage system 128 to apply the voltage, or the plurality of voltages, to the quantum dot related region 104 via the voltage output 114. The control system 132 may command, instruct, trigger, etc. the voltage system 128 to apply the voltage, or the plurality of voltages, at a magnitude (or plurality of magnitudes) and/or a duration (or a plurality of durations). The control system 132 may also command, instruct, trigger, etc. the voltage system 128 to apply the plurality of voltages at a number of discrete voltages (e.g., number of voltages in the plurality of voltages).

The magnitude of the voltage, or the magnitudes of the plurality of voltages, may be in a range of about −10 V to 10 V, for instance at least −10 V, at least −9 V, at least −8 V, at least −7 V, at least −6 V, at least −5 V, at least −4 V, at least −3 V, at least −2 V, at least −1 V, at least −0.5 mV, at least −0.3 mV, at least −0.1 mV, at least 0 V, at least 0.1 mV, at least 0.3 mV, at least 0.5 mV, at least 1 V, at least 2 V, at least 3 V, at least 4 V, at least 5 V, at least 6 V, at least 7 V, at least 8 V, at least 9 V, or at least 10 V. In some examples, the magnitude of the voltage, or the magnitudes of the plurality of voltages, are −10 V or less, −9 V or less, −8 V or less, −7 V or less, −6 V or less, −5 V or less, −4 V or less, −3 V or less, −2 V or less, −1 V or less, −0.5 mV or less, −0.3 mV or less, −0.1 mV or less, 0 V or less, 0.1 mV or less, 0.3 mV or less, 0.5 mV or less, 1 V or less, 2 V or less, 3 V or less, 4 V or less, 5 V or less, 6 V or less, 7 V or less, 8 V or less, 9 V or less, or 10 V or less.

In some examples, each position at which each quantum dot related region can be tested is connected to a separate voltage system, such as the voltage system 128, and each separate voltage system is connected to the control system 132. As such, each position at which each quantum dot related region can be tested may be received by the control system 132 as an identifier associated with an electrical connection to each separate voltage system (e.g., the control system 132 may be configured with an algorithm that may output each position from an input of one or more electrical connections). The control system 132 may command, instruct, trigger, etc. each separate voltage system to apply the voltage, or plurality of the voltages, to its respective quantum dot related region by referencing the identifier associated with each separate voltage system.

The current system 130 may be similarly electrically connected to each position at which each quantum dot related region can be tested (e.g., each position received by the control system 132). In some examples, the current system 130 is electrically connected via an electrical connection (e.g., cables, adaptors, etc.) to each position at which each quantum dot related region can be tested. For instance, current input 120 of the current system 130 may be connected to the position at which the quantum dot related region 104 can be tested, such as the electrodes 138, 140, 142, and/or 144. Similarly, current input 122 may be connected to the position at which the quantum dot related region 106 can be tested, and current input 124 may be connected to the position at which the quantum dot related region 108 can be tested. In some examples, the current system 130 measures current, or a plurality of current, at the same position at which the voltage system 128 applies the voltage, or the plurality of voltages. For instance, the position, received by the control system 132, at which the quantum dot related region 104 can be tested may be the electrode 138 (or 140, or 142, or 144). As such, the voltage system 128 and the current system 130 may be electrically connected to the electrode 138 (or 140, or 142, or 144). In some examples, the current system 130 measures the current, or the plurality of current, at a different position than the voltage system 128 applies the voltage, or the plurality of voltages. For instance, the control system 132 may receive a first position, such as the electrode 138, at which the voltage, or the plurality of voltages, can be applied to the quantum dot related region 104. The control system 132 may also receive a second position, such as the electrode 140, at which the current, or the plurality of current, can be measured from the quantum dot related region 104. As such, the voltage system 128 may be electrically connected to the first position, and the current system 130 may be electrically connected to the second position.

The current system 130 may also similarly be connected to the control system 132. The control system 132 may command, instruct, trigger, etc. the current system 130 to measure the current, or the plurality of currents, resulting from the voltage, or the plurality of voltages, at each position received by the control system 132. For instance, if the position at which quantum dot related region 104 can be tested is electrically connected to the current input 120 of the current system 130, the position received by the control system 132 for the quantum dot related region 104 may be an identifier A. As such, referencing the identifier A, the control system 132 may command, instruct, trigger, etc. the current system 130 to measure the current, or the plurality of currents, resulting from the voltage, or the plurality of voltages, at the quantum dot related region 104 via the current input 120. The control system 132 may command, instruct, trigger, etc. the current system 130 to measure the current, or the plurality of currents for a duration (or a plurality of durations). In some examples, each position at which each quantum dot related region can be tested is connected to a separate current system, such as the current system 130, and each separate current system is connected to the control system 132. As such, each position at which each quantum dot related region can be tested may be received by the control system 132 as an identifier associated with an electrical connection to each separate current system (e.g., the control system 132 may be configured with an algorithm that may output each position from an input of one or more electrical connections). The control system 132 may command, instruct, trigger, etc. each separate current system to measure current, or plurality of currents, from its respective quantum dot related region by referencing the identifier associated with each separate current system.

The control system 132 may receive the current, or the plurality of currents, measured at each position at which each quantum dot related region can be tested. The control system 132 may store, display, or process the current, or the plurality of currents, measured at each position. For instance, the control system 132 may create data associated with each position at which each quantum dot related region can be tested. In some examples, the control system 132 creates data associated with all positions at which quantum dot related regions can be tested. For instance, the data may include data associated with each position at which each quantum dot related region can be tested.

The data associated with each position at which each quantum dot related region can be tested may be the current, or the plurality of currents, measured at each position and/or the voltage, or the plurality of voltages, applied at each position. For instance, the data associated with each position may be a plurality of currents resulting from a constant applied voltage. The constant applied voltage may have any voltage magnitude described herein. In some examples, the data associated with each position is the plurality of currents resulting from the constant applied voltage and the constant applied voltage. In some examples, the data associated with each position is a plurality of currents resulting from a plurality of voltages, such that each current in the plurality of currents results from a voltage in the plurality of voltages. In some examples, the data associated with each position is the plurality of currents resulting from the plurality of voltages and the plurality of voltages.

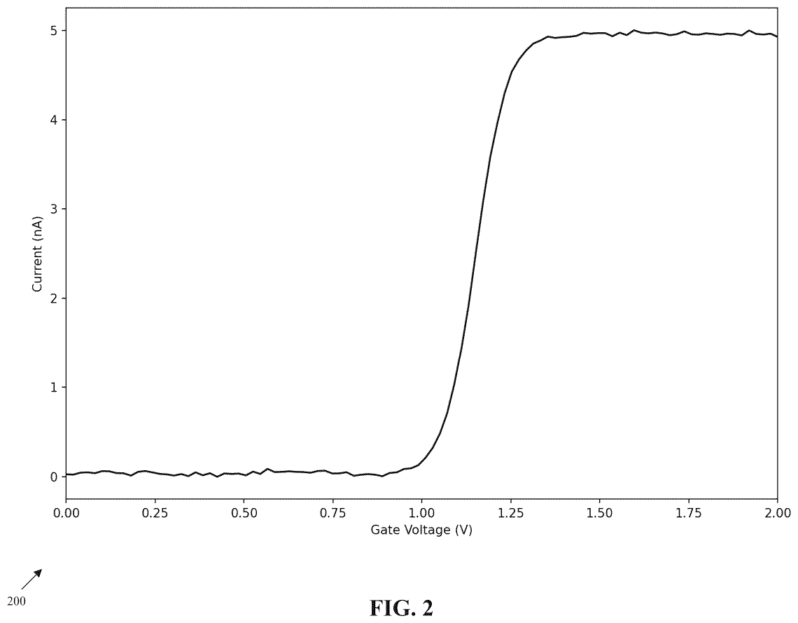

The control system 132 may plot the data associated with each position at which each quantum dot related region can be tested. For instance, the control system 132 may plot the plurality of currents resulting from the plurality of voltages versus the plurality of voltages (e.g., IV curve) for each position. FIG. 2 is an exemplary plot of a plurality of currents resulting from a plurality of voltages versus the plurality of voltages (e.g., IV curve) for a position at which a quantum dot related region can be tested. FIG. 2 illustrates an S-shaped transition from a low current to a high current as a function of voltage, which may indicate that the quantum dot related region is in the pinch-off regime, and thus, a quantum dot may be formed in the quantum dot related region (e.g., the quantum dot related region is a quantum dot forming region).

Referring to FIG. 1, a person of skill in the art will appreciate that the current system 130 may be configured to apply current, or a plurality of currents, to each position at which each quantum dot can be tested. Similarly, a person of skill in the art will appreciate that the voltage system 128 may be configured to measure voltage, or a plurality of voltages, resulting from the current, or the plurality of currents, at each position. With the current system 130 and the voltage system 128 configured as such, a person of skill in the art will appreciate that the above description is equally applicable.

In some examples, each quantum dot related region is tested by: 1) applying the voltage (or the plurality of voltages) to each position of each quantum dot related region (e.g., each position at which each quantum dot related region can be tested) received by the control system 132, 2) measuring a current (or a plurality of currents) induced in a quantum dot capacitively coupled to each quantum dot related region (e.g., a quantum dot capacitively coupled to one quantum dot related region), and 3) determining a conductance value (or a plurality of conductance values) of the quantum dot capacitively coupled to each quantum dot related region or determining one or more charge states of each quantum dot related region (e.g., charge sensing measurements). Applying the voltage to each position of each quantum dot related region using the voltage system 128 results in a current in each quantum dot related region, which in turn, induces a current in the quantum dot capacitively coupled to each quantum dot related region. The current induced in the quantum dot capacitively coupled to each quantum dot related region can be measured at a position of the quantum dot received by the control system 132 (e.g., a position at which the quantum dot can be tested). Each position of the quantum dot capacitively coupled to each quantum dot related region may be received by the control system 132 using any aforementioned method, such as received as a user input or an algorithm output. The quantum dot capacitively coupled to each quantum dot related region may be formed using any method that confines one or more charge carriers in each quantum dot related region, for instance electrostatically confining one or more charge carriers in each quantum dot related region by applying a voltage to one or more electrodes defining a quantum dot related region configured to form the quantum dot capacitively coupled to each quantum dot related region.

The current, or the plurality of currents, induced in the quantum dot capacitively coupled to each quantum dot related region may be measured with a current system, such as the current system 130. The control system 132 may receive the measured current, or the plurality of measured currents, and may use it and the voltage, or the plurality of voltages, applied to each position of each quantum dot related region to determine the conductance value, or the plurality of conductance values, of the quantum dot. The control system 132 may plot the conductance of the quantum dot versus the voltage, or the plurality of voltages. In some examples, the control system 132 may use the conductance of the quantum dot capacitively coupled to each quantum dot related region and the voltage, or the plurality of voltages, applied to each position of each quantum dot related region to determine the one or more charge states of each quantum dot related region. The control system 132 may plot the one or more charge states of each quantum dot related region versus the voltage, or the plurality of voltages.

The control system 132 may store, display, or additionally process the current, or the plurality of currents, measured at the quantum dot capacitively coupled to each quantum dot related region. For instance, the control system 132 may create data associated with each quantum dot related region. In some examples, the control system 132 creates data associated with all quantum dot related regions. For instance, the data may include data associated with each quantum dot related region.

The data associated with each quantum dot related region may be the current (or the plurality of currents) measured from each position of the quantum dot, the voltage (or the plurality of voltages) applied to each position of each quantum dot related region, the conductance value (or the plurality of conductance values) determined for each position of the quantum dot, and/or the one or more charge states determined for each quantum dot related region. For instance, the data associated with each quantum dot related region may be a plurality of currents measured from each position of the quantum dot and resulting from a constant voltage applied to each position of each quantum dot related region. The constant applied voltage may have any voltage magnitude described herein. Alternatively, the data associated with each quantum dot related region may be a plurality of conductance values determined from the plurality of measured currents and the constant applied voltage. In some examples, the data may be one or more charge states of each quantum dot related region determined from the plurality of conductance values. In some examples, the data associated with each quantum dot related region is the plurality of currents resulting from the constant applied voltage and the constant applied voltage. In some examples, the data is the plurality of conductance values and the constant applied voltage. In some examples, the data is the one or more charge states of each quantum dot related region and the constant applied voltage.

In some examples, the data associated with each quantum dot related region is a plurality of currents measured from each position of the quantum dot capacitively coupled to each quantum dot related region and resulting from a plurality of voltages applied to each position of each quantum dot related region. Each current in the plurality of currents may result from a voltage in the plurality of voltages. Alternatively, the data associated with each quantum dot related region may be a plurality of conductance values determined from the plurality of currents and the plurality of voltages. In some examples, the data may be one or more charge states determined from the plurality of conductance values. In some examples, the data associated with each quantum dot related region is the plurality of currents resulting from the plurality of voltages and the plurality of voltages. In some examples, the data associated with each quantum dot related region is the plurality of conductance values and the plurality of voltages. In some examples, the data associated with each quantum dot related region is the one or more charge states and the plurality of voltages.

In some examples, each quantum dot related region is tested by reflectometry measurements, such as radio frequency (RF) reflectometry, in which measuring the amplitude and/or phase of a reflected electromagnetic signal (e.g., such as an RF electromagnetic signal) yields data associated with impedance variations, resistance variations, and/or capacitance variations of each quantum dot related region. For reflectometry measurements, an inductor (L) capacitor (C) tank circuit (e.g., impedance matching circuit) may be fabricated on a printed circuit board (PCB) for each quantum dot related region and electrically connected to each quantum dot related region by soldering, wire bonding, etc. (e.g., each quantum dot related region may be electrically connected to its own LC tank circuit). For instance, each LC circuit may be electrically connected to the one or more electrodes defining each quantum dot related region of the semiconductor quantum device 102. Each LC tank circuit may be connected to the one or more source electrodes, the one or more drain electrodes, and/or the one or more gate electrodes of the one or more electrodes defining each quantum dot related region. In some examples, each LC tank circuit is electrically connected to the one or more current/voltage traces connecting to the one or more electrodes defining each quantum dot related region.

An inductance of the inductor and a capacitance of the capacitor of each LC tank circuit may be configured such that an impedance of each quantum dot related region matches an impedance of each transmission input into each circuit defined by each LC tank circuit and each quantum dot related region. The impedance of each transmission input may be matched for a transmission input of an electromagnetic signal at a resonant frequency of the circuit. Each transmission input may be any combination of cables, attenuators, amplifiers, adaptors, etc. configured to transmit the electromagnetic signal from an electromagnetic signal generating system to each circuit. The electromagnetic signal generating system may be any system configured to output the electromagnetic signal to each transmission input, such as a lock-in amplifier, arbitrary waveform generator, signal generator, etc. The electromagnetic signal generating system may output the electromagnetic signal via a command, instruction, trigger, etc. from the control system 132. The command, instruction, trigger, etc. from the control system 132 may define a frequency, duration, amplitude, phase, etc. of the electromagnetic signal.

A resonant frequency of the circuit may be determined from the inductance and capacitance of the inductor and capacitor, respectively. In some examples, one or more resonant frequencies of the circuit may be determined by: 1) applying a plurality of electromagnetic signals of a plurality of frequencies to the circuit, 2) measuring the amplitude of the plurality of electromagnetic signals reflected from the circuit (e.g., each quantum dot related region), and 3) determining a frequency (or frequencies) of the electromagnetic signal at which the measured amplitude is at a minimum. In some examples, the one or more resonant frequencies of the circuit are previously determined using the aforementioned method and stored by the control system 132.

The electromagnetic signal may be applied to each circuit (e.g., to each quantum dot related region) via the transmission input. The reflected electromagnetic signal may be measured with any system configured to measure the amplitude and/or phase of an electromagnetic signal, for instance a network analyzer, a spectrum analyzer, a lock-in amplifier, etc. The frequency of the electromagnetic signal applied to each circuit may be a resonant frequency of each circuit. While the electromagnetic signal is applied to each circuit, a voltage, or a plurality of voltages, may be applied to each position of each quantum dot related region (e.g., each position at which each quantum dot related region can be tested).

Due to the aforementioned impedance matching of each circuit for electromagnetic signals at the resonant frequency of the circuit, changes in the impedance, resistance, and/or capacitance of each quantum dot related region from the applied voltage (or plurality of applied voltages) generates changes in the amplitude and/or phase of the reflected electromagnetic signal. As such, measuring the amplitude and/or phase of the reflected electromagnetic signal yields an amplitude (and/or phase), or a plurality of amplitudes (and/or a plurality of phases) of the reflected electromagnetic signal which may indicate whether a quantum dot may be formed in each quantum dot related region. The control system 132 may store, display, or additionally process the measured amplitude and/or phase or the plurality of measured amplitudes and/or phases. For instance, the control system 132 may create data associated with each quantum dot related region. In some examples, the control system 132 creates data associated with all quantum dot related regions. For instance, the data may include data associated with each quantum dot related region.

The data associated with each quantum dot related region may be the amplitude (and/or phase) or the plurality of amplitudes (and/or the plurality of phases) of the reflected electromagnetic signal and/or the voltage (or the plurality of voltages) applied at each position of each quantum dot related region. For instance, the data associated with each quantum dot related region may be a plurality of amplitudes (and/or plurality of phases) of the reflected electromagnetic signal measured while a constant voltage is applied to each quantum dot related region. The constant applied voltage may have any voltage magnitude described herein. In some examples, the data associated with each position is the plurality of amplitudes (and/or plurality of phases) and the constant applied voltage. In some examples, the data associated with each position is a plurality of amplitudes (and/or a plurality of phases) of the reflected electromagnetic signal, such that each amplitude (and/or phase) is measured while a voltage of a plurality of voltages is applied to each position of each quantum dot related region. In some examples, the data associated with each quantum dot related region is the plurality of amplitudes (and/or the plurality of phases) and the plurality of voltages.

In some examples, each quantum dot related region is tested by a combination of reflectometry measurements and charge sensing measurements, in which measuring the amplitude and/or phase of a reflected electromagnetic signal (e.g., such as an RF electromagnetic signal) yields data associated with impedance variations, resistance variations, and/or capacitance variations of a quantum dot capacitively coupled to each quantum dot related region (e.g., each quantum dot related region is capacitively coupled to one quantum dot). The LC tank circuit (e.g., impedance matching circuit) may similarly be fabricated on a printed circuit board (PCB) for each quantum dot and electrically connected to the quantum dot capacitively coupled to each quantum dot related region by soldering, wire bonding, etc. For instance, each LC circuit may be electrically connected to the one or more electrodes used to form the quantum dot. The LC tank circuit may be connected to one or more source electrodes, one or more drain electrodes, and/or one or more gate electrodes of the one or more electrodes. In some examples, each LC tank circuit is electrically connected to one or more current/voltage traces connecting to the one or more electrodes used to form the quantum dot.

The inductance of the inductor and the capacitance of the capacitor of the LC tank circuit may similarly be configured such that an impedance of each quantum dot related region matches an impedance of each transmission input into each circuit defined by each LC tank circuit electrically connected to a quantum dot and each quantum dot related region. The impedance of each transmission input may be matched for a transmission input of an electromagnetic signal at a resonant frequency of the circuit. One or more resonant frequencies of each circuit may be determined using the aforementioned methods, such as described in reference to the reflectometry measurements.

The electromagnetic signal may be applied to the circuit (e.g., to each quantum dot related region) via the transmission input. The reflected electromagnetic signal may be measured with any system configured to measure the amplitude and/or phase of an electromagnetic signal, for instance a network analyzer, a spectrum analyzer, a lock-in amplifier, etc. The electromagnetic signal may have a frequency at a resonant frequency of each circuit.

The control system 132 may command, instruct, trigger, etc. the voltage system 128 to apply the voltage, or the plurality of voltages, to each position of each quantum dot related region. Applying the voltage to each position of each quantum dot related region results in a current in each quantum dot related region, which in turn, induces a current in the quantum dot capacitively coupled to each quantum dot related region (e.g., induces a change in the impedance of the quantum dot). Due to the aforementioned impedance matching of each quantum dot related region for electromagnetic signals at the resonant frequency of each circuit, changes in the impedance, resistance, and/or capacitance of the quantum dot generates changes in the amplitude and/or phase of the reflected electromagnetic signal. As such, measuring the amplitude and/or phase of the reflected electromagnetic signal yields an amplitude (and/or phase), or a plurality of amplitudes (and/or a plurality of phases), of the reflected electromagnetic signal. The control system 132 may receive the measured amplitude (and/or phase), or the plurality of measured amplitudes (and/or phases). The control system 132 may plot the measured amplitude (and/or phase) or the plurality of amplitudes (and/or the plurality of phases) versus the voltage, or the plurality of voltages applied to each position of each quantum dot related region. In some examples, the control system 132 may use the measured amplitude (and/or phase) or the plurality of amplitudes (and/or the plurality of phases) and the voltage, or the plurality of voltages, to determine the one or more charge states of each quantum dot related region. The control system 132 may plot the one or more charge states of each quantum dot related region versus the voltage, or the plurality of voltages applied to each position of each quantum dot related region. The control system 132 may store, display, or additionally process the measured amplitude and/or phase, or the plurality of measured amplitudes and/or plurality of phases. For instance, the control system 132 may create data associated with each quantum dot related region. In some examples, the control system 132 creates data associated with all quantum dot related regions. For instance, the data may include data associated with each quantum dot related region.

The data associated with each quantum dot related region may be the amplitude (and/or phase) or the plurality of amplitudes (and/or the plurality of phases) of the reflected electromagnetic signal or the voltage (or the plurality of voltages) applied at each position of each quantum dot related region. For instance, the data associated with each quantum dot related region may be a plurality of amplitudes (and/or plurality of phases) of the reflected electromagnetic signal measured while a constant voltage is applied to each quantum dot related region. The constant applied voltage may have any voltage magnitude described herein. In some examples, the data associated with each quantum dot related region is the plurality of amplitudes (and/or plurality of phases) and the constant applied voltage. In some examples, the data associated with each position is a plurality of amplitudes (and/or the plurality of phases) of the reflected electromagnetic signal, such that each amplitude (and/or phase) is measured while a voltage of a plurality of voltages is applied to each position of each quantum dot related region. In some examples, the data associated with each quantum dot related region is the plurality of amplitudes (and/or the plurality of phases) and the plurality of voltages.

Input the Data for Each Quantum Dot Related Region into a Model

The system 100 may include a trained model 134 configured to identify (e.g., classify) a quantum dot forming region based on whether an input associated with the quantum dot related region represents a quantum dot forming region. The trained model 134 may be a trained support vector machine model, a trained K-nearest neighbor model, a trained decision tree model, a trained artificial neural network model (e.g., trained convolutional neural network model, trained recurrent neural network model, or trained attention-based neural network model), a trained logistic regression model, a trained naïve Bayes model, a trained linear discriminant analysis model, or a trained quadratic discriminant analysis model. The input to the trained model 134 may be the data associated with each position at which each quantum dot related region can be tested. In some examples, the input to the trained model 134 is the data associated with each quantum dot related region, such as described in reference to charge sensing measurements, reflectometry, and a combination of charge sensing measurements and reflectometry. In some examples, the input to the trained model 134 is the data associated with all positions at which all quantum dot related regions can be tested as the input. In some examples, the input to the trained model 134 is the data associated with all quantum dot related regions, such as described in reference to charge sensing measurements, reflectometry, and the combination of charge sensing measurements and reflectometry. In some examples, the input to the trained model 134 is data associated with one or more quantum dot related regions that is received by the control system 132 from one or more third parties. For instance, the data may be current, or a plurality of currents, and/or voltage, or a plurality of voltages, associated with one or more quantum dot related regions that is published or otherwise made available by industry, academia, or government. In some examples, the data from one or more third parties is data obtained from charge sensing measurements, reflectometry, and/or a combination of charge sensing measurements and reflectometry, such as described herein.

The trained model 134 may use the input to classify each quantum dot related region as to whether each quantum dot related region(s) associated with the input is a quantum dot forming region. For instance, the trained model 134 may attempt to identify one or more features in the input indicative of a quantum dot forming region. The one or more features indicative of a quantum dot forming region may be an S-shaped transition from a low current (or high current) to a high current (or low current) as a function of voltage, such as depicted in FIG. 2. The S-shaped transition from the low current to the high current may indicate that applying a plurality of voltages to the quantum dot related region induces a transition from a non-conductive state to a conductive state (e.g., the pinch-off regime), thus quantum dot related region may be a quantum dot forming region.

The trained model 134 may produce one or more outputs indicating whether the input represents a quantum dot forming region(s). For instance, the trained model 134 may produce a binary label, such that a first state of the binary label indicates the input represents a quantum dot forming region and a second state of the binary label indicates the input represents a quantum dot non-forming region (e.g., a quantum dot cannot be formed in the quantum dot related region(s) associated with the input). The trained model 134 may produce a likelihood that the input represents a quantum dot forming region(s). For instance, the trained model 134 may produce a probability that the input represents a quantum dot forming region or a confidence score that the input represents a quantum dot forming region. For a probability greater than or equal to 0.5 or a confidence score greater than or equal to 0.5, the input may be considered to represent a quantum dot forming region.

The trained model 134 may be a part of the control system 132. For instance, the control system 132 may input data associated with a position at which a first quantum dot related region can be tested or data associated with a first quantum dot related region (e.g., such as the data described in reference to charge sensing measurements, reflectometry, or a combination of charge sensing measurements and reflectometry) into the trained model 134. The control system 132 may then command, instruct, trigger, etc. the trained model 134 to classify the first quantum dot related region using the input. The control system 132 may then receive one or more outputs indicating whether the input associated with the first quantum dot related region represents a quantum dot forming region. The control system 132 may then input data associated with a position at which a second quantum dot related region can be tested or data associated with a second quantum dot related region into the trained model 134. The control system 132 may then command, instruct, trigger, etc. the trained model 134 to classify the second quantum dot related region using the input. The control system 132 may then receive one or more outputs indicating whether the input associated with the second quantum dot related region represents a quantum dot forming region. The process may be continued for data associated with each position at which each quantum dot related region can be tested and/or data associated with each quantum dot related region. In some examples, inputting the data associated with the position at which the quantum dot related region can be tested or data associated with each quantum dot related region into the trained model 134 may trigger the trained model 134 to classify the quantum dot related region. In some examples, the control system inputs data associated with all positions at which all quantum dot related regions can be tested or data associated with all quantum dot related regions into the trained model 134. The control system may then command, instruct, trigger, etc. the trained model 134 to sequentially classify each quantum dot related region using data associated with each position or each quantum dot related region that is included in the inputted data. In some examples, the control system may command, instruct, trigger, etc. the trained model 134 to in parallel classify each position or each quantum dot related region using the data associated with each position or quantum dot related region that is included in the inputted data. The control system 132 may receive one or more outputs indicating whether each quantum dot related region associated with the input is a quantum dot forming region. The control system 132 may store, display, or process the one or more outputs produced by the trained model 134. The control system 132 may use the one or more outputs produced by the trained model 134 to determine whether one or more operation parameters should be determined for the one or more quantum dot related regions associated with the input. For instance, if no quantum dot related regions are categorized by the trained model 134 as quantum dots forming regions, the control system 132 may determine no operation parameters for the quantum dot related regions. However, if one or more quantum dot related regions are categorized by the trained model 134 as quantum dot forming regions, the control system 132 may determine one or more operation parameters for the quantum dot forming regions.

### Determining One or More Operation Parameters

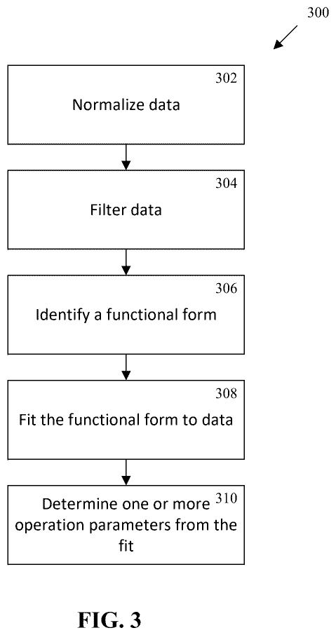

FIG. 3 illustrates an exemplary method 300 for determining one or more operation parameters for one or more quantum dot forming regions. The one or more quantum dot forming regions may be identified using a system configured to identify quantum dot forming regions, such as system 100 of FIG. 1. The method 300 may be performed by a control system, such as control system 132 of FIG. 1. In some examples, the method 300 is performed in accordance with a system configured to identify quantum dot forming regions, such as system 100 of FIG. 1, such that a control system (e.g., such as control system 132) may use one or more outputs from a trained model (e.g., such as trained model 134) to determine whether the method 300 should be performed for one or more quantum dot related regions associated with one or more inputs to the trained model. The method 300 may be performed for each quantum dot forming region of the one or more quantum dot forming regions. In some examples, the method 300 is performed for each quantum dot forming region of a subset of the one or more quantum dot forming regions.

In step 302, data associated with each quantum dot forming region may be normalized. The data associated with each quantum dot forming region may be normalized to one or more values in a range of 0 to 1, which may reduce scale dependencies of the data associated with each quantum dot forming region.

The data associated with each quantum dot forming region may be data associated with its respective quantum dot related region prior to being identified as a quantum dot forming using a system configured to identify quantum dot forming regions, such as system 100 of FIG. 1. As such, the data associated with each quantum dot forming region may be the current, or the plurality of currents, previously measured and stored using a system configured to identify quantum dot forming regions, such as system 100 of FIG. 1. The data associated with each quantum dot forming region may also be the voltage, or the plurality of voltages, previously applied and stored using a system configured to identify quantum dot forming regions, such as system 100 of FIG. 1. The data associated with each quantum dot forming region may be data previously obtained from charge sensing measurements, reflectometry, and/or a combination of charge sensing measurements and reflectometry measurements (e.g., such as described in reference to FIG. 1) and stored using a system configured to identify quantum dot forming regions, such as system 100 of FIG. 1.

The data associated with each quantum dot forming region may also be obtained by testing a position of each quantum dot forming region using a voltage system (e.g., such as voltage system 128 of FIG. 1) and a current system (e.g., such as current system 130 of FIG. 1) and stored for later processing using a control system (e.g., such as control system 132 of FIG. 1), such as described in reference to FIG. 1. The data associated with each region may also be obtained by charge sensing measurements, reflectometry, and/or a combination of charge sensing measurements and reflectometry, such as described in reference to FIG. 1. In some examples, the data associated with each quantum dot forming region may be data received from one or more third parties. For instance, the data may be data associated with one or more quantum dot forming regions that is published or otherwise made available by industry, academia, or government, such as data described in reference to FIG. 1. Such data may be received by a control system, such as control system 132 of FIG. 1.

In step 304, the data associated with each quantum dot forming region may be filtered. The data may be filtered with a Gaussian filter, a filter generated by a neural network, or a sober filter. The filtering may reduce noise and outliers in the data. In some examples, the step 302 and/or the step 304 are not performed, such that the data is not normalized and/or filtered. In some examples, the step 304 is performed prior to the step 302, such that the data is filtered and then normalized.

In step 306, a functional form (e.g., equation) may be identified that represents the data associated with each quantum dot forming region. For instance, if the data includes an S-shaped transition from a low current (or high current) to a high current (or low current), such as depicted in FIG. 2 (e.g., IV curve), the functional form that represents such data may be a sigmoid function, such as a logistic function or a hyperbolic tangent (e.g., Equation 1):

$$f ( x , a , b , c ) = a ( 1 + tanh ( b x + c ) ) , \qquad Equation 1$$

where a, b, and c are parameters that parameterize the amplitude, steepness, and horizontal offset, respectively. In some examples, a user identifies the functional form that represents the data associated with each quantum dot forming region and inputs the functional form into a control system, such as control system 132 of FIG. 1. In some examples, the control system identifies the functional form based on one or more features in the data associated with each quantum dot forming region, such as the one or more features a trained model 134 attempts to identify when identifying each quantum dot forming region, such as described in reference to FIG. 1. In some examples, the same functional form is identified for each quantum dot forming region. In some examples, a different functional form is identified for each quantum dot forming region. In some examples, the functional form that represents the data associated with each quantum dot forming region is already known, such that the step 306 is not performed.

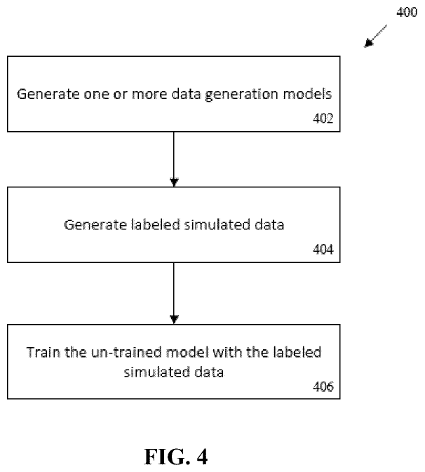

In step 308, the functional form identified in the step 306 may be fit to the data associated with each quantum dot forming region using an optimization algorithm, which may be any optimization algorithm configured to fit and/or optimize the fitting of the functional form to the data. For instance, the optimization algorithm may be a nonlinear least squares optimization, a Nelder-Mead optimization, or a gradient descent optimization. The optimization algorithm may be performed by a control system, such as control system 132 of FIG. 1. The control system may receive one or more initial starting conditions prior to fitting the data. The one or more initial starting conditions may be based on simulated data (e.g., such as described in FIG. 4), previously obtained data, or previously used initial starting conditions. The control system may receive parameter bounds for each parameter that parameterizes the functional form, such as the parameters a, b, and c of the hyperbolic tangent functional form (e.g., Equation 1). The parameter bounds may similarly be based on simulated data (e.g., such as described in FIG. 4), previously obtained data, or previously used parameter bounds. The control system may use the one or more initial starting conditions and/or the parameter bounds to begin fitting the data associated with each quantum dot forming region to the functional form using the optimization algorithm. The control system may iteratively adjust the parameters parameterizing the functional form to minimize the error between the data and the functional form. The control system may stop the numerical optimization when the error between the data and the functional form reaches a pre-determined error threshold.

In step 310, one or more operation parameters of each quantum dot forming region are determined using the functional form fitted to the data associated with each quantum dot forming region. The one or more operation parameters of each quantum dot forming region may be a current or voltage value, such that applying the current or voltage value to each quantum dot forming region operates each quantum dot forming region and/or forms a quantum dot in each quantum dot forming region. The control system, or a user, may determine the one or more operation parameters by identifying a current(s) and/or voltage value(s) of the fitted functional form that is associated with a feature inherent to each operation parameter of the one or more operation parameters. For instance, the control system, or the user, may determine a cutoff voltage operation parameter by identifying the voltage value at which the fitted functional form drops below a pre-defined threshold. The cutoff voltage operation parameter may represent the onset of conduction for each quantum dot forming region. The control system, or the user, may determine a transition voltage operation parameter by identifying the voltage value at which the fitted functional form has a maximum slope. The transition voltage operation parameter may represent the rapid change between a conductive state and a non-conductive state of each quantum dot forming region. The control system, or the user, may determine a saturation voltage operation parameter by identifying the voltage value at which the fitted functional form flattens to a maximum current value. The saturation voltage operation parameter may represent a stable conducting region of each quantum dot forming region.

The systems and methods described herein for identifying one or more quantum dot forming regions of a semiconductor quantum device and determining one or more operation parameters for one or more quantum dot forming regions may be technically more advantageous than conventional systems and methods. For instance, conventional systems and methods attempt to determine operation parameters of all quantum dot related regions, regardless of whether the quantum dot related regions may be quantum dot forming regions. As such, the conventional systems and methods yield unreliable or inaccurate operation parameters. Furthermore, the conventional systems and methods often struggle to determine operation parameters from noisy or incomplete data associated with the quantum dot forming regions. The systems and methods described herein may determine one or more operation parameters only for quantum dot forming regions. Thus, the one or more operation parameters for each quantum dot forming region may be more accurate and precise. Additionally, the one or more initial starting conditions and the one or more parameter bounds may be based on simulated data and/or previously obtained data associated with the quantum dot forming regions. As such, the one or more initial starting conditions and the one or more parameter bounds may be configured to be more refined, which may further yield more accurate and consistent operation parameters of each quantum dot forming region.

Additionally, the conventional systems and methods identify quantum dot related regions as quantum dot forming regions by visually examining data associated with the quantum dot related regions in manual or semi-automated methods. The conventional manual or semi-automated methods are often time-consuming, inaccurate, and unscalable. As such, the manual or semi-automated methods may limit the applicability of quantum dots in applications, like quantum computing, that require identifying a great number of quantum dot forming regions. In the systems and methods described herein, the quantum dot forming regions may be identified using a trained model (e.g., such as trained model 134 of FIG. 1) that can rapidly and automatically process large batches of data, which enables high-throughput identification of quantum dot forming regions that may be configured to form quantum dots. Additionally, the trained model may be configured to handle a variety of data including data with excessive noise, reduced signal-to-noise-ratio, incomplete information, etc. because the trained model is trained using a broad data distribution (e.g., broad range of current and voltage values), a broad quantum dot parameter distribution, and/or data with various noise profiles.

### Training a Model Configured to Identify Quantum Dot Forming Regions

FIG. 4 illustrates a method 400 of training an un-trained model with labeled simulated data generated by one or more data generation models modeling quantum behavior of quantum dot(s). In step 402, the one or more data generation models modeling quantum behavior of one or more quantum dots may be generated. The one or more data generation models may be generated by a control system, such as control system 132 of FIG. 1. For instance, the one or more data generation models modeling quantum behavior of the one or more quantum dots may be generated by the control system using one or more equations and/or one or more algorithms configured to model quantum behavior of one or more quantum dots. The quantum behavior modeled by the one or more models may be associated with, or be a consequence of, a plurality of parameters of the one or more quantum dots (e.g., a broad quantum dot parameter distribution). For instance, the quantum behavior may be associated with electron temperature of the one or more quantum dots, tunnel coupling strength of the one or more quantum dots, and/or background charge disorder of the one or more quantum dots. The one or more data generation models may be stored, displayed, or used by the control system. The one or more data generation models may use a simulated voltage, or a plurality of simulated voltages, as an input, in which simulated voltage is a voltage that could be applied to a position at which a quantum dot related region can be tested, such as described in reference to FIG. 1. In some examples, the one or more data generation models also use a simulated electromagnetic signal with a resonant frequency of a circuit as an input, in which simulated electromagnetic signal is an electromagnetic signal that could be applied to the circuit, such as described in reference to FIG. 1. The circuit may be defined by an LC tank circuit electrically connected to a quantum dot capacitively coupled to a region that may be designed to be configured to form a quantum dot, such as described in reference to FIG. 1. The circuit may alternatively be defined by an LC tank circuit electrically connected to a region that may be designed to be configured to form a quantum dot, such as described in reference to FIG. 1.

The one or more data generation models may output a simulated current, or a plurality of simulated currents, in which simulated current is a current that could be measured at a position at which a quantum dot related region can be tested or measured at a position of a quantum dot capacitively coupled to a quantum dot related region, such as described in reference to FIG. 1. The one or more data generation models may output a simulated amplitude (and/or simulated phase), or a plurality of simulated amplitudes (and/or simulated phases) of a simulated reflected electromagnetic signal, in which simulated amplitude (and/or simulated phase) is an amplitude (and/or a phase) of a reflected electromagnetic signal that may be measured, such as described in reference to FIG. 1. The one or more data generation models may output a simulated conductance value, or a plurality of simulated conductance values, in which simulated conductance value is a conductance value that could be determined from a measured current (or a plurality of measured currents) induced in a quantum dot capacitively coupled to a quantum dot related region by applying a voltage (or a plurality of voltages), such as described in reference to FIG. 1. The one or more data generation models may output a one or more simulated charge states, in which simulated charge state could be determined for a quantum dot related region that may be designed to be configured to be a quantum dot using the conductance value, or the plurality of conductance values, determined for a quantum dot capacitively coupled to the quantum dot related region. A person of skill in the art will appreciate that the one or more data generation models may be configured to use any of the aforementioned inputs as outputs and any of the aforementioned outputs as inputs.

In step 404, the simulated voltage, or the plurality of simulated voltages, and/or the simulated electromagnetic signal may be inputted into the one or more data generation models and the output may be produced, such that the output is any of the aforementioned outputs. For instance, a control system, such as control system 132 of FIG. 1, may input the simulated voltage, or the plurality of simulated voltages, into the one or more data generation models. The control system may then command, instruct, trigger, etc. the one or more data generation models to simulate quantum behavior of one or more quantum dots using the simulated voltage, or the plurality of simulated voltages. The one or more data generation models may output the simulated current, or the plurality of simulated currents. In some examples, inputting the simulated voltage, or the plurality of simulated voltages, and/or the simulated electromagnetic signal into the one or more data generation models triggers the one or more data generation models to simulate the quantum behavior of the one or more quantum dots. The output from the one or more data generation models may be recorded, stored, displayed, or used by the control system.

In some examples, a simulated voltage of a constant value is inputted into the one or more data generation models, and a plurality of simulated currents are recorded by the control system. In some examples, a plurality of simulated voltages is inputted into the one or more data generation models, such that each voltage in the plurality of simulated voltages is a different value. The control system may record a simulated current, or a plurality of simulated currents, for each value of the simulated voltage in the plurality of simulated voltages. In some examples, the plurality of simulated currents recorded for each value of the simulated voltage may be averaged, thus forming a simulated current for each value of the simulated voltage in the plurality of simulated voltages. The simulated voltage, or the plurality of simulated voltages, and the simulated current, or the plurality of simulated currents, may include a broad range of voltage values and current values. In some examples, any of the aforementioned inputs may include a broad range of values (e.g., voltage values, frequencies of electromagnetic signal, amplitude of electromagnetic signal, etc.). In some examples, any of the aforementioned outputs may include a broad range of values (e.g., current values, amplitude values, phase values, conductance values, charge states, etc.) In some examples, any of the aforementioned inputs and/or any of the aforementioned outputs may be injected with, overlaid with, or otherwise subjected to, one or more noise profiles, such as a Gaussian noise profile, a 1/f noise profile, and/or a baseline shift noise profile. In some examples, the step 404 is repeated, such that after N repetitions, the control system recorded N simulated currents, or N pluralities of simulated currents, in response to N simulated voltages, or N pluralities of simulated voltages. In some examples, the step 404 is repeated, such that after N repetitions, the control system recorded N outputs, such as any data generation model output described herein, in response to N inputs, such as any data generation model input described herein. The simulated voltage, or the plurality of simulated voltages, and the simulated current, or the plurality of simulated currents, may be labeled. For instance, it may be known a priori that inputting a simulated voltage, or a plurality of simulated voltages, yields a simulated current, or a plurality of simulated currents that indicates a quantum dot may be formed or may not be formed. As such, after N repetitions of the step 404, the control system may record N labeled simulated currents, or N pluralities of labeled simulated currents, in response to N labeled simulated voltages, or N pluralities of labeled simulated voltages. Similarly, it may be known a priori that one or more inputs yields one or more outputs that indicates a quantum dot may be formed or may not be formed. As such, after N repetitions of the step 404, the control system may record N labeled outputs in response to N labeled inputs.

In step 406, labeled simulated data may be used to train an untrained model. The labeled simulated data may be the labeled inputs to the one or more data generation models and/or the labeled outputs of the one or more data generation models described in the step 406. In some examples, the labeled simulated data may be the N labeled inputs and/or the N labeled outputs. The un-trained model may be an untrained support vector machine model, an untrained K-nearest neighbor model, an untrained decision tree model, an untrained artificial neural network model (e.g., an untrained convolutional neural network model, an untrained recurrent neural network model, or an untrained attention-based neural network model), an untrained logistic regression model, an untrained naïve Bayes model, an untrained linear discriminant analysis model, or an untrained quadratic discriminant analysis model. In some examples, the untrained model is on the control system, and the control system commands, instructs, triggers, etc. the training of the untrained model. For instance, the control system may assign, input, or otherwise associate the labeled simulated data as an input of the untrained model. In some examples, the control system may normalize the labeled simulated data and then assign, input, or otherwise associate the normalized labeled simulated data and/or the normalized labeled empirical data as an input of the untrained model. The control system may command, instruct, trigger, etc. the untrained model to train using the input. For instance, if the untrained model is an untrained artificial neural network model, the untrained model may train by iteratively adjusting network weights via backpropagation. The output of the training is a trained model, such as trained model 134 of FIG. 1, which may be used by the systems and methods disclosed herein to identify quantum dot forming regions. The performance of the trained model may be evaluated using a variety of metrics, such as F1 score, precision, recall, accuracy, or confusion matrix.

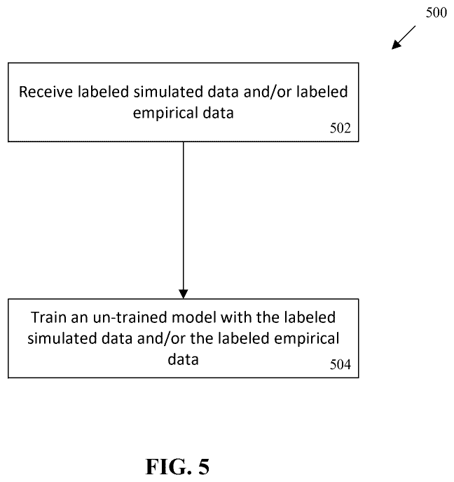

The un-trained model may be trained using both labeled simulated data and/or labeled empirical data. FIG. 5 illustrates an exemplary method 500 for training an un-trained model with labeled simulated data and/or labeled empirical data. In a step 502, labeled simulated data and/or labeled empirical data may be received. For instance, the labeled simulated data and/or labeled empirical data may be received by a control system, such as control system 132 of FIG. 1. The labeled simulated data may be obtained in steps 402-404 of method 400 in FIG. 4. The labeled simulated data may be labeled inputs to one or more data generation models and/or labeled outputs from the one or more data generation models, such as described in step 404 of method 400 in FIG. 4. In some examples, the simulated data is previously obtained. For instance, the labeled simulated data may be previously obtained using steps 402-404 of method 400 of FIG. 4 and then stored by a control system, such as control system 132 of FIG. 1, for later use. In some examples, the labeled simulated data is obtained from a third-party. For instance, the labeled simulated data may be labeled simulated data published or otherwise made available by industry, academia, or government. The empirical data may be obtained using system 100 of FIG. 1 by: 1) receiving positions at which quantum dot related regions, of one or more semiconductor quantum devices, can be tested, and 2) testing the positions. The empirical data may include measured current, or a plurality of measured current, and/or applied voltage, or a plurality of applied voltages. The empirical data may include data obtained from charge sensing measurements, reflectometry, and/or a combination of charge sensing measurements and reflectometry, such as described in reference to FIG. 1. In some examples, the empirical data is obtained from a third-party. For instance, the empirical data may be empirical data published or otherwise made available by industry, academia, or government. In some examples, the empirical data is previously measured, such as measured using system 100 of FIG. 1 and then stored by a control system, such as control system 132 of FIG. 1, for later use. In some examples, M sets of simulated data and B sets of empirical data are received. M and B may be any integer greater than or equal to 1, and M and B may be the same, or different, integer.

In some examples, the empirical data is not labeled, such that it may be relevant to label the empirical data. The labeling may indicate whether the empirical data indicates a quantum dot can be formed. The empirical data may be labeled by a user. For instance, the user may visually examine the empirical data to identify one or more features indicating a quantum dot may be formed. If the one or more features are present, the empirical data may be labeled as indicating a quantum dot may be formed. If the one or more features are not present, the empirical data may be labeled as indicating a quantum dot may not be formed. In some examples, the empirical data is labeled by a control system, such as control system 132 of FIG. 1. The control system may attempt to identify one or more dramatic, obvious, or otherwise easily programmable features indicating a quantum dot may be formed. If one or more such features are present, the empirical data may be labeled as indicating a quantum dot may be formed. If one or more such features are not present, the empirical data may be labeled as indicating a quantum dot may not be formed.

In step 504, the labeled simulated data and/or the labeled empirical data are used to train an untrained model, such as the untrained model described in step 406 of method 400 of FIG. 4. For instance, the control system may assign, input, or otherwise associate the labeled simulated data and/or the labeled empirical data as an input of the untrained model. In some examples, the control system may normalize the labeled simulated data and/or the labeled empirical data, and then assign, input, or otherwise associate the normalized labeled simulated data and/or the normalized labeled empirical data as an input of the untrained model. The control system may command, instruct, trigger, etc. the untrained model to train using the input. For instance, if the untrained model is an untrained artificial neural network model, the untrained model may train by iteratively adjusting network weights via backpropagation. The output of the training is a trained model, such as trained model 134 of FIG. 1, which may be used by the systems and methods disclosed herein to identify quantum dot forming regions. The performance of the trained model may be evaluated using a variety of metrics, such as F1 score, precision, recall, accuracy, or confusion matrix. In some examples, the M sets of labeled simulated data and/or the B sets of labeled empirical data are used to train the un-trained model (e.g., assigned as the input of the un-trained model by the control system).

### Method for Determining One or More Operation Parameters of Quantum Dot Forming Regions

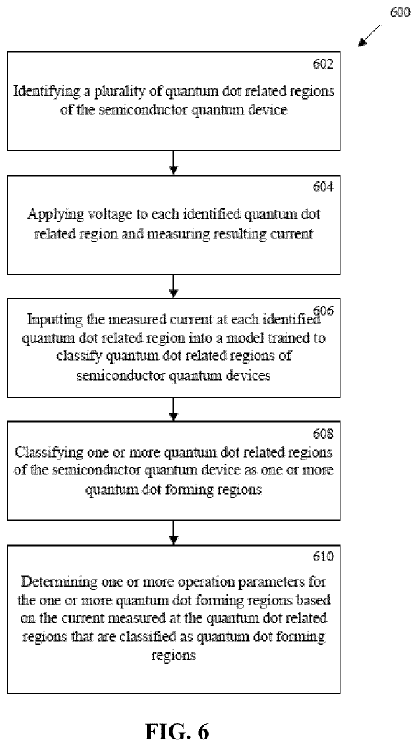

FIG. 6 illustrates an exemplary method 600 for determining one or more operation parameters of one or more quantum dot forming regions. In step 602, positions for a plurality of quantum dot related regions of a semiconductor quantum device are received (e.g., quantum dot related regions may be identified). The semiconductor quantum device may be any semiconductor quantum device described herein, such as semiconductor quantum device 102 of FIG. 1. The quantum dot related regions of the semiconductor quantum device may be any quantum dot related regions described herein, such as quantum dot related regions 104, 106, and 108 of FIG. 1. The positions for a plurality of quantum dot related regions may be received by a control system, such as control system 132 of FIG. 1. Each position of the positions may be a position at which each quantum dot related region can be tested, such as described in reference to FIG. 1.

In step 604, voltage may be applied to each of the plurality of positions of quantum dot related regions and current, resulting from the applied voltage, may be measured (e.g., applying voltage to each identified quantum dot related region and measuring the resulting current). Each of the plurality of positions may refer to each of the plurality of positions of the quantum dot related regions (e.g., applying voltage and measuring current at all received positions). In some examples, each of the plurality of positions refers to a subset of each of the plurality of positions of the quantum dot related regions (e.g., applying voltage and measuring current at a subset of the received positions).

The voltage may be applied by a voltage system, such as voltage system 128 of FIG. 1. The voltage system may be simultaneously connected to the control system and each position at which each quantum dot related region can be tested, such as described in reference to FIG. 1. The current may be measured by a current system, such as current system 130 of FIG. 1. The current system may be simultaneously connected to the control system and each position at which each quantum dot related region can be tested, such as described in reference to FIG. 1. In some examples, the control system is electrically connected to the same position as the voltage system, such as described in reference to FIG. 1. In some examples, the control system is electrically connected to a different position than the voltage system, such as described in reference to FIG. 1. The voltage applied to each of the plurality of positions of quantum dot related regions may be a constant voltage, and the measured current resulting from the constant applied voltage may be a plurality of measured currents. The voltage applied to each of the plurality of positions of quantum dot related regions may be a plurality of applied voltages. The measured current resulting from the plurality of applied voltages may be a plurality of measured currents, such that a current, or a plurality of currents, is measured for each voltage in the plurality of applied voltages (e.g., such as depicted in FIG. 2). The control system may measure, store, display, or use the measured current, or the plurality of measured currents, and/or the applied voltage, or the plurality of applied voltages.

In some examples, the voltage or the plurality of voltages are applied to each position and a current, or a plurality of currents, is measured from a position of a quantum dot capacitively coupled to each quantum dot related region (e.g., charge sensing measurements). The control system may receive the measured current, or the plurality of measured currents. The control system may use the measured current, or the plurality of measured currents, and the applied voltage, or the plurality of applied voltages, to determine a conductance value or a plurality of conductance values of the quantum dot capacitively coupled to each quantum dot related region. The control system may use the conductance value, or the plurality of conductance values, to determine one or more charge states of each quantum dot related region. In some examples, the voltage or the plurality of voltages are applied to each position and an amplitude (and/or a phase), or a plurality of amplitudes (and/or a plurality of phases), of an electromagnetic signal reflected from a circuit is measured, in which the circuit is defined by an LC tank circuit electrically connected to each quantum dot related region (e.g., reflectometry measurements). In some examples, the voltage or the plurality of voltages are applied to each position and an amplitude (and/or phase), or a plurality of amplitudes (and/or a plurality of phases) of an electromagnetic signal reflected from a circuit is measured, in which the circuit is defined by an LC tank circuit electrically connected to a quantum dot capacitively coupled to each quantum dot related region (e.g., charge sensing and reflectometry measurements). The control system may use the amplitude (and/or phase), or the plurality of amplitudes (and/or plurality of phases), to determine one or more charge states of each quantum dot related region.

In step 606, the measured current at each of the plurality of positions of quantum dot related regions may be inputted into a model trained to classify quantum dot related regions (e.g., inputting measured current at each identified quantum dot related region into a model trained to classify quantum dot related regions). The model trained to classify quantum dot related regions may be any trained model described herein, such as trained model 134 of FIG. 1. The model may be trained using method 400 of FIG. 4 or method 500 of FIG. 5. The trained model may be a part of the control system, such that the control system: 1) inputs the measured current at each of the plurality of positions of quantum dot related regions into the trained model, 2) triggers the trained model to classify each of the plurality of positions of quantum dot related regions, and 3) receives, stores, displays, or uses one or more outputs from the trained model generated for each input that indicates whether the input represents a quantum dot forming region. The one or more outputs from the trained model may be a binary label, such that a first state of the binary label indicates the input to the trained model represents a quantum dot forming region and a second state of the binary label indicates the input to the trained model represents quantum dot non-forming region. The output from the trained model may be a probability or a confidence score indicating a likelihood that the input to the trained model represents quantum dot forming region. In some examples, the plurality of measured currents at each of the plurality of positions of quantum dot related regions is inputted into the trained model. In some examples, the plurality of measured currents and the voltage applied at each of the plurality of positions of quantum dot related regions is inputted into the trained model. In some examples, the plurality of measured currents and the plurality of voltages applied at each of the plurality of positions of quantum dot related regions is inputted into the trained model. In some examples, the conductance value (or the plurality of conductance values) and the applied voltage (or the plurality of applied voltages) is inputted into the trained model. In some examples, the one or more charge states and the applied voltage (or the plurality of applied voltages) is inputted into the trained model. In some examples, the amplitude (and/or phase) (or the plurality of amplitudes and/or the plurality of phases) and the applied voltage (or the plurality of applied voltages) is inputted into the trained model.

In step 610, one or more operation parameters for one or more quantum dot forming regions may be determined if one or more quantum dot related regions are classified as quantum dot forming regions. The one or more operation parameters may be determined using method 300 of FIG. 3. The one or more operation parameters may be any operation parameters described herein, such as the cutoff voltage, transition voltage, and saturation voltage operation parameters described in reference to step 310 of method 300 of FIG. 3. In some examples, the one or more operation parameters are determined based on the plurality of measured current, such as described in method 300 of FIG. 3. In some examples, the one or more operation parameters are determined based on the plurality of measured current and the applied voltage, such as described in method 300 of FIG. 3. In some examples, the one or more operation parameters are determined based on the plurality of measured current and the plurality of applied voltages, such as described in method 300 of FIG. 3. In some examples, the one or more operation parameters are determined based on the conductance value (or the plurality of conductance values) and the applied voltage (or the plurality of applied voltages), such as described in method 300 of FIG. 3. In some examples, the one or more operation parameters are determined based on the one or more charge states and the applied voltage (or the plurality of applied voltages), such as described in method 300 of FIG. 3. In some examples, the one or more operation parameters are determined based on the amplitude (and/or phase) (or the plurality of amplitudes and/or the plurality of phases) and the applied voltage (or the plurality of applied voltages), such as described in method 300 of FIG. 3. The one or more operation parameters for the one or more quantum dot forming regions of the semiconductor quantum device may be used to form a quantum dot in each quantum dot forming region and/or operate the one or more quantum dot forming regions. For instance, the one or more operation parameters may be used to operate the one or more quantum dot forming regions for quantum applications and/or additional quantum dot systems and methods.

### Quantum Device

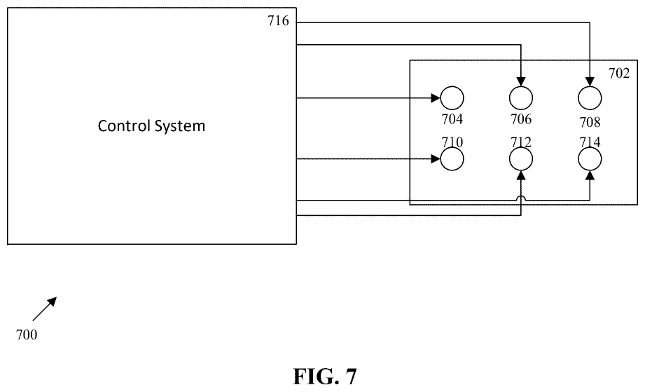

FIG. 7 is an exemplary embodiment of a quantum device 700 with one or more quantum dot forming regions that are each configured to operate using one or more operation parameters. The quantum device 700 includes a semiconductor quantum device 702. The semiconductor quantum device 702 may be any semiconductor quantum device described herein, such as semiconductor quantum device 102 of FIG. 1. The semiconductor quantum device 702 includes one or more quantum dot forming regions, such as quantum dot forming regions 704, 706, 708, 710, 712, and/or 714. The one or more quantum dot forming regions may be identified as quantum dot forming regions using the systems and methods described herein, such as system 100 of FIG. 1 or method 600 of FIG. 6. The one or more operation parameters for each of the one or more quantum dot forming regions may be determined using the systems and methods described herein, such as method 300 of FIG. 3 or step 610 of method 600 of FIG. 6. The quantum device 700 includes a control system 716 configured to operate each quantum dot forming region using its one or more operation parameters (e.g., operate the quantum device 700), configured to calibrate a quantum dot in each quantum dot forming region using its one or more operation parameters, and/or configured to form a quantum dot in each quantum dot forming region using its one or more operation parameters. Operating each quantum dot forming region may refer to operating each quantum dot forming region of the one or more quantum dot forming regions of the semiconductor quantum device 702. In some examples, operating each quantum dot forming region refers to operating each quantum dot forming region of a subset of the one or more quantum dot forming regions. The control system 716 may be configured to determine the one or more operation parameters of each quantum dot forming region, such as described in method 300 of FIG. 3 and method 600 of FIG. 6.

In some examples, the one or more quantum dot forming regions are configured to operate at a temperature, T. The temperature, T, may be in a range of about 1 mK to 10,000 mK, for instance at least 1 mK, at least 10 mK, at least 20 mK, at least 30 mK, at least 40 mK, at least 50 mK, at least 60 mK, at least 70 mK, at least 80 mK, at least 90 mK, at least 100 mK, at least 200 mK, at least 300 mK, at least 400 mK, at least 500 mK, at least 600 mK, at least 700 mK, at least 800 mK, at least 900 mK, or at least 1,000 mK, at least 2,000 mK, at least 3,000 mK, at least 4,000 mK, at least 5,000 mK, at least 6,000 mK, at least 7,000 mK, at least 8,000 mK, at least 9,000 mK, at least 10,000 mK. In some examples, the temperature, T, is at most 1 mK, at most 10 mK, at most 20 mK, at most 30 mK, at most 40 mK, at most 50 mK, at most 60 mK, at most 70 mK, at most 80 mK, at most 90 mK, at most 100 mK, at most 200 mK, at most 300 mK, at most 400 mK, at most 500 mK, at most 600 mK, at most 700 mK, at most 800 mK, at most 900 mK, or at most 1,000 mK, at most 2,000 mK, at most 3,000 mK, at most 4,000 mK, at most 5,000 mK, at most 6,000 mK, at most 7,000 mK, at most 8,000 mK, at most 9,000 mK, at most 10,000 mK. The quantum device 700 may be used in quantum applications, like quantum computing, or additional quantum dot systems and methods. For instance, the quantum device 700 may be used in the additional quantum dot systems and methods that measure Coulomb blockade oscillations (e.g., peaks in a plot of measured current versus applied voltage) or charge stability diagrams.

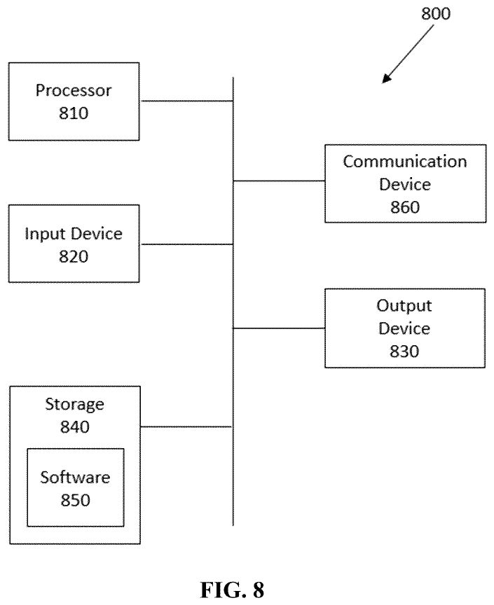

FIG. 8 illustrates an example of a computing system 800 that may be used for any one of the computing systems and devices described herein, such as for control system 132 of FIG. 1. System 800 can be a computer connected to a network. System 800 can be a client computer, a server, a router, a hub, an access point, or any other computing device that can send and/or receive wireless signals or non-wireless signals. In some examples, system 800 is a component of a microchip that also includes a quantum device, such as quantum device 700 of FIG. 7. As shown in FIG. 8, system 800 can be any suitable type of microprocessor-based system, such as a personal computer, workstation, server, or handheld computing device (portable electronic device) such as a phone or tablet. The system can include, for example, one or more of a processor 810, input device 820, output device 830, storage 840, and communication device 860. Input device 820 and output device 830 can generally correspond to those described above and can either be connectable or integrated with the computer.

Input device 820 can be any suitable device that provides input, such as a touch screen, keyboard or keypad, mouse, gesture recognition component of a virtual/augmented reality system, or voice recognition device. Output device 830 can be or include any suitable device that provides output, such as a touch screen, haptics device, virtual/augmented reality display, or speaker.

Storage 840 can be any suitable device that provides storage, such as an electrical, magnetic, or optical memory, including a RAM, cache, hard drive, removable storage disk, or other non-transitory computer-readable medium. Communication device 860 can include any suitable device capable of transmitting and receiving signals over a network, such as a network interface chip or device. The components of the computer can be connected in any suitable manner, such as via a physical bus or wirelessly.

Software 850, which can be stored in storage 840 and executed by processor 810, can include, for example, the programming that embodies the functionality of the present disclosure (e.g., as embodied in the devices as described above). For example, software 850 can include one or more programs for performing one or more of the steps of method 300 of FIG. 3, method 400 of FIG. 4, method 500 of FIG. 5, or method 600 of FIG. 6.

Software 850 can also be stored and/or transported within any non-transitory computer-readable storage medium for use by or in connection with an instruction execution system, apparatus, or device, such as those described above, that can fetch instructions associated with the software from the instruction execution system, apparatus, or device and execute the instructions. In the context of this disclosure, a computer-readable storage medium can be any medium, such as storage 840, that can contain or store programming for use by or in connection with an instruction execution system, apparatus, or device.

Software 850 can also be propagated within any transport medium for use by or in connection with an instruction execution system, apparatus, or device, such as those described above, that can fetch instructions associated with the software from the instruction execution system, apparatus, or device and execute the instructions. In the context of this disclosure, a transport medium can be any medium that can communicate, propagate, or transport programming for use by or in connection with an instruction execution system, apparatus, or device. The transport-readable medium can include, but is not limited to, an electronic, magnetic, optical, electromagnetic, or infrared wired or wireless propagation medium.

System 800 may be connected to a network, which can be any suitable type of interconnected communication system. The network can implement any suitable communications protocol and can be secured by any suitable security protocol. The network can comprise network links of any suitable arrangement that can implement the transmission and reception of network signals, such as wireless network connections, T1 or T3 lines, cable networks, DSL, or telephone lines.

System 800 can implement any operating system suitable for operating on the network. Software 850 can be written in any suitable programming language, such as C, C++, Java, or Python. In various aspects, application software embodying the functionality of the present disclosure can be deployed in different configurations, such as in a client/server arrangement or through a Web browser as a Web-based application or Web service, for example.

The foregoing description, for the purpose of explanation, has been described with reference to specific aspects. However, the illustrative discussions above are not intended to be exhaustive or to limit the invention to the precise forms disclosed. Many modifications and variations are possible in view of the above teachings. The aspects were chosen and described in order to best explain the principles of the techniques and their practical applications. Others skilled in the art are thereby enabled to best utilize the techniques and various aspects with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosures of the patents and publications referred to in this application are hereby incorporated herein by reference.

1. A method for determining operation parameters for one or more quantum dot forming regions of a semiconductor quantum device, the method comprising:
identifying a plurality of quantum dot related regions of the semiconductor quantum device;
applying voltage to each identified quantum dot related region and measuring resulting current;
classifying one or more quantum dot related regions of the semiconductor quantum device as the one or more quantum dot forming regions by inputting the measured current at each identified quantum dot related region into a model trained to classify quantum dot related regions of semiconductor quantum devices based on measured current; and
determining one or more operation parameters for the one or more quantum dot forming regions based on the current measured at the quantum dot related regions that are classified as quantum dot forming regions.

2. The method of claim 1, wherein a composition of the semiconductor quantum device comprises Group-IV semiconductors, Group-IV compound semiconductors, doped semiconductors, or Group-III and Group-V compound semiconductors.

3. The method of claim 1, wherein applying the voltage to each identified quantum dot related region and measuring the resulting current comprises:
applying a constant voltage and measuring a plurality of resulting currents, wherein the constant voltage is applied to one or more electrodes of each quantum dot related region of the plurality of quantum dot related regions; or
applying a plurality of voltages and measuring the resulting current for each voltage in the plurality of voltages, wherein the plurality of voltages is applied to the one or more electrodes of each quantum dot related region in the plurality of quantum dot related regions.

4. The method of claim 1, wherein inputting the measured current into the model trained to classify the quantum dot related regions comprises at least:
inputting a plurality of measured currents;
inputting a constant voltage applied to each identified quantum dot related region; or
inputting a plurality of voltages applied to each identified quantum dot related region.

5. The method of claim 1, wherein the model is a support vector machine model, a K-nearest neighbor model, a decision tree model, an artificial neural network model, a logistic regression model, a naïve Bayes model, a linear discriminant analysis model, or a quadratic discriminant analysis model.

6. The method of claim 1, wherein training the model trained to classify the quantum dot related regions comprises training an un-trained model with one or more labeled simulated currents or the one or more labeled simulated currents and one or more labeled simulated voltages.

7. The method of claim 6, wherein obtaining the one or more labeled simulated currents comprises:
generating one or more data generation models representing quantum behavior of one or more quantum dots; and
inputting the one or more labeled simulated voltages to the one or more data generation models and receiving the one or more labeled simulated currents.

8. The method of claim 1, wherein training the model trained to classify the quantum dot related regions further comprises training an un-trained model with one or more labeled measured currents or the one or more labeled measured currents and one or more voltages applied to the one or more quantum dot related regions.

9. The method of claim 8, wherein obtaining the one or more labeled measured currents comprises:
obtaining one or more measured currents from one or more quantum dot related regions of one or more semiconductor quantum devices, wherein the one or more measured currents is obtained by applying one or more voltages to the one or more quantum dot related regions of the one or more semiconductor quantum devices and measuring resulting current; and
labeling the one or more measured currents based on whether the one or more measured currents indicate the one or more quantum dot related regions are quantum dot forming regions.

10. The method of claim 1, wherein classifying each of the quantum dot related regions of the semiconductor quantum device using the model trained to classify the quantum dot related regions comprises receiving from the model one or more outputs for each of the plurality of quantum dot related regions, wherein the one or more outputs from the model is:
a binary label, wherein a first state of the binary label indicates that a quantum dot related region is a quantum dot forming region and a second state of the binary label indicates that the quantum dot related region is quantum dot non-forming region;
a probability, wherein the probability indicates a likelihood that the quantum dot related region is the quantum dot forming region; or
a confidence score, wherein the confidence score indicates a likelihood that the quantum dot related region is the quantum dot forming region.

11. The method of claim 1, wherein determining the one or more operation parameters for each quantum dot forming region of the one or more quantum dot forming regions based on the measured current at the quantum dot related regions comprises:
fitting a functional form to the measured current using an optimization algorithm; and
determining the one or more operation parameters using the fitted functional form.

12. The method of claim 11, further comprising:
normalizing the measured current and applying a filter to the normalized measured current; or
applying the filter to the measured current and normalizing the filtered measured current.

13. The method of claim 11, wherein determining the one or more operation parameters based on the measured current further comprises determining the one or more operation parameters based on a plurality of measured currents, the plurality of measured currents and an applied voltage, or the plurality of measured currents and a plurality of applied voltages.

14. The method of claim 11, wherein the functional form is a hyperbolic tangent function parameterized with three parameters, wherein the three parameters parameterize amplitude, steepness, and horizontal offset.

15. The method of claim 11, wherein the optimization algorithm fits a filtered and normalized measured current by adjusting parameters parameterizing the functional form.

16. The method of claim 15, wherein adjusting the parameters parameterizing the functional form comprises minimizing an error between the filtered and normalized measured current and the functional form.

17. The method of claim 11, wherein determining the one or more operation parameters from the fit comprises identifying onset of conduction, change between non-conductive and conductive states, or stable conduction, wherein the onset of the conduction is a cutoff voltage, the change between the non-conductive and the conductive states is a transition voltage, and the stable conduction is a saturation voltage.

18. The method of claim 1, wherein the semiconductor quantum device operates at temperatures in a range of 1 mK to 10,000 mK.

19. The method of claim 1, wherein the one or more operation parameters are used to operate the one or more quantum dot forming regions of the semiconductor quantum device.

20. A quantum device comprising one or more quantum dot forming regions, wherein each quantum dot forming region is configured to operate using one or more operation parameters, comprising:
a semiconductor quantum device; and
a control system, comprising one or more processors, configured to:
operate the quantum device comprising the one or more quantum dot forming regions using the one or more operation parameters of each quantum dot forming region, wherein the one or more operation parameters of each quantum dot forming region have been determined by:
identifying a plurality of quantum dot related regions of the semiconductor quantum device;
applying voltage to each identified quantum dot related region and measuring resulting current;
classifying one or more quantum dot related regions of the semiconductor quantum device as the one or more quantum dot forming regions by inputting the measured current at each identified quantum dot related region into a model trained to classify quantum dot related regions of semiconductor quantum devices based on measured current; and
determining the one or more operation parameters for the one or more quantum dot forming regions based on the current measured at the quantum dot related regions that are classified as quantum dot forming regions.
